(19) United States
(12) Patent Application Publication
(10) Pub. No.: US 2023/0111888 A1
(43) Pub. Date: Apr. 13, 2023

(54) QUANTUM DOT COMPOSITE AND LIGHT EMITTING DIODE INCLUDING THE SAME

(71) Applicant: Samsung Display Co., Ltd., Yongin-si (KR)

(72) Inventors: HYEKYOUNG CHOI, Hwaseong-si (KR); YUNKU JUNG, Cheonan-si (KR); SUNGWOON KIM, Hwaseong-si (KR)

(21) Appl. No.: 17/889,236

(22) Filed: Aug. 16, 2022

(30) Foreign Application Priority Data
Oct. 7, 2021 (KR) 10-2021-0133147

(51) Int. Cl. C09K 11/02; H01L 51/00; H01L 51/50

(52) U.S. Cl. CPC C09K 11/025; H01L 51/005; H01L 51/502; B82Y 20/00

(57) ABSTRACT

A quantum dot composite includes: a quantum dot; and a ligand bonded to a surface of the quantum dot, wherein a plurality of binding portions to which the ligand is bonded are provided on the surface of the quantum dot, wherein the binding portions include: a first binding portion in which cations are exposed; a second binding portion in which anions are exposed; and a third binding portion in which the cations and the anions are bonded to each other and exposed, and the ligand includes: a first ligand bonded to the first binding portion; a second ligand bonded to the second binding portion; and a third ligand bonded to the third binding portion. Accordingly, a light emitting diode including the quantum dot composite of an embodiment as a light emitting material may have increased luminous efficiency.

### CROSS-REFERENCE TO RELATED APPLICATIONS

This application claims priority to and the benefit of Korean Patent Application No. 10-2021-0133147, filed on Oct. 7, 2021, the entire content of which is incorporated herein by reference.

### BACKGROUND

The present disclosure herein relates to a quantum dot composite and a light emitting element (e.g., light emitting diode) including the same, and for example, to a quantum dot composite having increased luminous efficiency and a light emitting element (e.g., light emitting diode) including the same.

Various types (kinds) of display devices utilized for multimedia devices such as a television set, a mobile phone, a tablet computer, a navigation system, and/or a game console are being developed. In such display devices, a so-called self-luminescent display element is utilized, which accomplishes display by causing an organic compound-containing light emitting material to emit light.

In addition, the development of a light emitting element (e.g., light emitting diode) utilizing quantum dots as a light emitting material is underway in an effort to enhance the color reproducibility of display devices, and there is a demand for increasing the service life (e.g., lifespan) and luminous efficiency of the light emitting element (e.g., light emitting diode) utilizing quantum dots.

### SUMMARY

An aspect according to embodiments of the present disclosure is directed toward a quantum dot composite that is utilized in an emission layer of a light emitting element (e.g., light emitting diode) to exhibit improved luminous efficiency characteristics.

An aspect according to embodiments of the present disclosure is also directed toward a light emitting element (e.g., light emitting diode) having increased luminous efficiency by including quantum dots having a plurality of different kinds of ligands bonded to a surface thereof in an emission layer.

According to an embodiment of the present disclosure, a quantum dot composite includes: a quantum dot having a surface including a plurality of binding portions; and a ligand bonded to the surface of the quantum dot, wherein the plurality of binding portions includes: a first binding portion in which cations are exposed; a second binding portion in which anions are exposed; and a third binding portion in which the cations and the anions are bonded to each other and exposed, and the ligand includes: a first ligand bonded to the first binding portion; a second ligand bonded to the second binding portion; and a third ligand bonded to the third binding portion.

In an embodiment, the first ligand may include an electron-donating head portion bonded to the first binding portion, the second ligand may include an electron-withdrawing head portion bonded to the second binding portion, and the third ligand may include a coordination-binding head portion bonded to the third binding portion.

In an embodiment, the electron-donating head portion may be at least one group selected from halide ions, carboxylate, phosphinate, phosphonate, phosphonic acid anhydride, alkoxylate, dithiolate, and thiolate; the electron-withdrawing head portion may be at least one metal atom selected from Mg, Ca, Sc, Sn, Ti, V, Cr, Mn, Fe, Co, Ni, Cu, Zn, Ga, Sr, Y, Zr, Nb, Mo, Cd, In, Ba, Au, Hg, and Tl; and the coordination-binding head portion may be at least one group selected from phosphine, phosphine oxide, amine, imidazole, and pyridine.

In an embodiment, at least one of the first ligand, the second ligand, or the third ligand may further include a tail portion, and the tail portion may be a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms.

In an embodiment, the first ligand may include the electron-donating head portion and a first tail portion connected to the electron-donating head portion; the second ligand may include the electron-withdrawing head portion, a connection portion connected to the electron-withdrawing head portion, and a second tail portion connected to the connection portion; and the third ligand may include the coordination-binding head portion and a third tail portion connected to the coordination-binding head portion.

In an embodiment, the quantum dot may include a core and a shell around (e.g., surrounding) the core.

In an embodiment, the first binding portion, the second binding portion, and the third binding portion may each be provided on a surface of the shell.

In an embodiment, the core may include a first semiconductor nanocrystal; the shell may include a second semiconductor nanocrystal different from the first semiconductor nanocrystal; and the first semiconductor nanocrystal and the second semiconductor nanocrystal may each be selected from a Group II-VI compound, a Group III-V compound, a Group IV-VI compound, a Group IV element, a Group IV compound, and a combination thereof.

In an embodiment, the second semiconductor nanocrystal may be in a state of having the cations and the anions bonded to each other.

In an embodiment, the first ligand may be represented by Formula 1-1 or Formula 1-2, the second ligand may be represented by Formula 2, and the third ligand may be represented by Formula 3.

A₁-R₁. Formula 1-1

In Formula 1-1 above, A₁ is at least one group selected from carboxylate, phosphinate, phosphonate, phosphonic acid anhydride, alkoxylate, dithiolate, and thiolate, and R₁ is a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms.

A₂, Formula 1-2

In Formula 1-2 above, A₂ is a halide ion.

M-A₃-R₂. Formula 2

In Formula 2 above, M is a metal atom selected from Mg, Ca, Sc, Sn, Ti, V, Cr, Mn, Fe, Co, Ni, Cu, Zn, Ga, Sr, Y, Zr, Nb, Mo, Cd, In, Ba, Au, Hg, and Tl, A₃ is at least one group selected from carboxylate, phosphinate, phosphonate, phosphonic acid anhydride, alkoxylate, dithiolate, and thiolate, and R₂ is a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms.

A₄-R₃. Formula 3

In Formula 3 above, A₄ is at least one group selected from phosphine, phosphine oxide, amine, imidazole, and pyridine, and R₃ is a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms.

In an embodiment of the present disclosure, a quantum dot composite includes: a quantum dot having a surface; and a ligand bonded to the surface of the quantum dot, wherein the ligand includes: a first ligand including an electron-donating head portion; a second ligand including an electron-withdrawing head portion; and a third ligand including a coordination-binding head portion.

In an embodiment, the quantum dot may include a core and a shell around (e.g., surrounding) the core, and the electron-donating head portion, the electron-withdrawing head portion, and the coordination-binding head portion may each be bonded to a surface of the shell.

In an embodiment of the present disclosure, a light emitting diode includes: a first electrode; a hole transport region on the first electrode; an emission layer on the hole transport region and including a quantum dot composite including a ligand; an electron transport region on the emission layer; and a second electrode on the electron transport region, wherein the quantum dot composite includes: a quantum dot having a surface; and the ligand bonded to the surface of the quantum dot, wherein the surface of the quantum dot includes a plurality of binding portions, the plurality of binding portions including: a first binding portion in which cations are exposed; a second binding portion in which anions are exposed; and a third binding portion in which the cations and the anions are bonded to each other and exposed, and the ligand includes: a first ligand bonded to the first binding portion; a second ligand bonded to the second binding portion; and a third ligand bonded to the third binding portion.

In an embodiment, the electron transport region may include an electron transport layer on the emission layer, and an electron injection layer between the electron transport layer and the second electrode, wherein the electron transport layer may include a metal oxide.

In an embodiment, the emission layer may have a central emission wavelength of about 500 nm to about 540 nm.

### BRIEF DESCRIPTION OF THE FIGURES

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a perspective view showing an electronic device according to an embodiment of the present disclosure;

FIG. 2 is an exploded perspective view of an electronic device according to an embodiment of the present disclosure;

FIG. 3 is a cross-sectional view of a display device according to an embodiment of the present disclosure;

FIG. 4 is a cross-sectional view of a light emitting diode according to an embodiment of the present disclosure;

FIG. 5 is a cross-sectional view showing a portion of a light emitting diode according to an embodiment of the present disclosure;

FIG. 6 is a schematic illustration showing one or more processes in a method for manufacturing a light emitting diode according to an embodiment of the present disclosure;

FIG. 7 is a schematic illustration showing a quantum dot composition according an embodiment of the present disclosure;

FIG. 8 is a schematic illustration showing a quantum dot and a ligand included in a quantum dot composition of an embodiment;

FIGS. 9A-9C are each a schematic illustration showing a form in which a ligand included in a quantum dot composition according to an embodiment of the present disclosure is bonded to a quantum dot surface;

FIG. 10 is a schematic illustration showing one or more processes in a method for manufacturing a light emitting diode according to an embodiment of the present disclosure;

FIG. 11 is a plan view of a display device according to an embodiment of the present disclosure;

FIG. 12 is a cross-sectional view of a display device according to an embodiment of the present disclosure;

FIG. 13 is a cross-sectional view of a display device according to an embodiment of the present disclosure;

FIG. 14 is a graph showing photoluminescence quantum yield as a function of wavelength in display devices according to Examples and Comparative Examples;

FIG. 15 is a graph showing photoluminescence quantum yield as a function of luminance in display devices according to Examples and Comparative Examples; and

FIG. 16 is a graph showing changes in luminance as a function of time in display devices according to Examples and Comparative Examples.

### DETAILED DESCRIPTION

Hereinafter, embodiments of the present disclosure will be described in more detail with reference to the accompanying drawings.

In this specification, it will also be understood that when a component (a region, a layer, a portion, and/or the like) is referred to as “being on”, “being connected to”, or “being coupled to” another component, it may be directly on/connected to/coupled to the other component, or an intervening third component may be also disposed therebetween.

Like reference numerals refer to like elements. In addition, in the drawings, the thickness, the ratio, and/or the dimensions of elements may be exaggerated for an effective description of technical contents. The term “and/or” includes any and all combinations of one or more of the associated listed items.

It will be understood that, although the terms “first,” “second,” etc. may be used herein to describe various elements, these elements should not be limited by these terms. These terms are only used to distinguish one element from another element. For example, a first element may be referred to as a second element, and similarly, a second element may be referred to as a first element, without departing from the teachings of the present disclosure. The terms of a singular form are intended to include the plural forms as well, unless the context clearly indicates otherwise.

In addition, terms such as “below,” “lower,” “above,” “upper,” and/or the like are used to describe the relationship of the configurations shown in the drawings. These terms are used as a relative concept, and are described with reference to the directions indicated in the drawings.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

As used herein, being “disposed directly on” may refer to that there is no additional layer, film, region, plate, and/or the like between a part and another part such as a layer, a film, a region, a plate, and/or the like. For example, being “disposed directly on” may refer to that two layers or two members are disposed without utilizing an additional member such as an adhesive member, therebetween.

Unless otherwise defined, all terms (including technical and scientific terms) used herein have the same meaning as commonly understood by one of ordinary skill in the art to which the present disclosure pertains. It is also to be understood that terms defined in commonly used dictionaries should be interpreted as having meanings consistent with the meanings in the context of the related art, and will not be interpreted in an idealized or overly formal sense unless expressly so defined herein.

Hereinafter, a quantum dot composition according to an embodiment of the present disclosure, a light emitting element (e.g., a light emitting diode), and a display device including the same will be described with reference to the accompanying drawings.

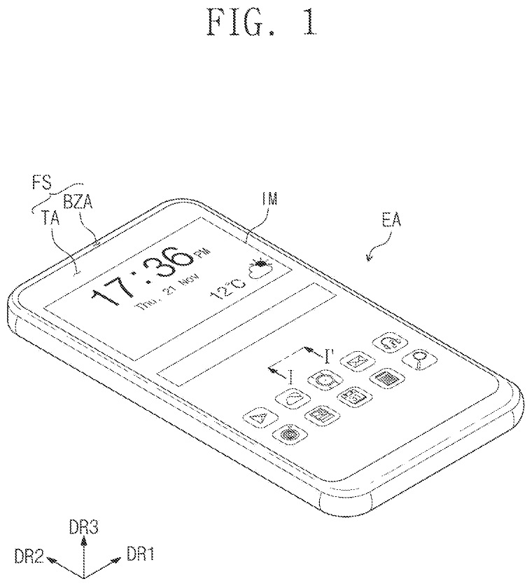

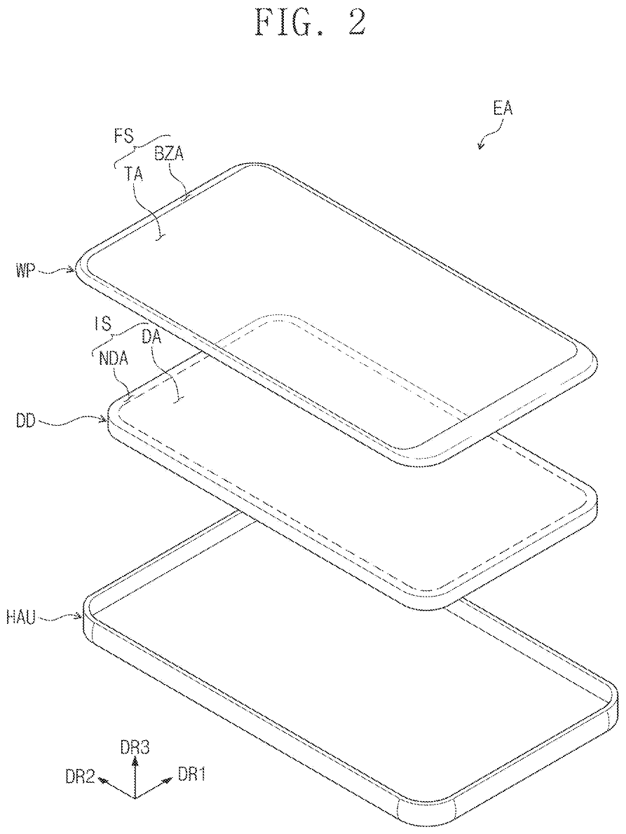

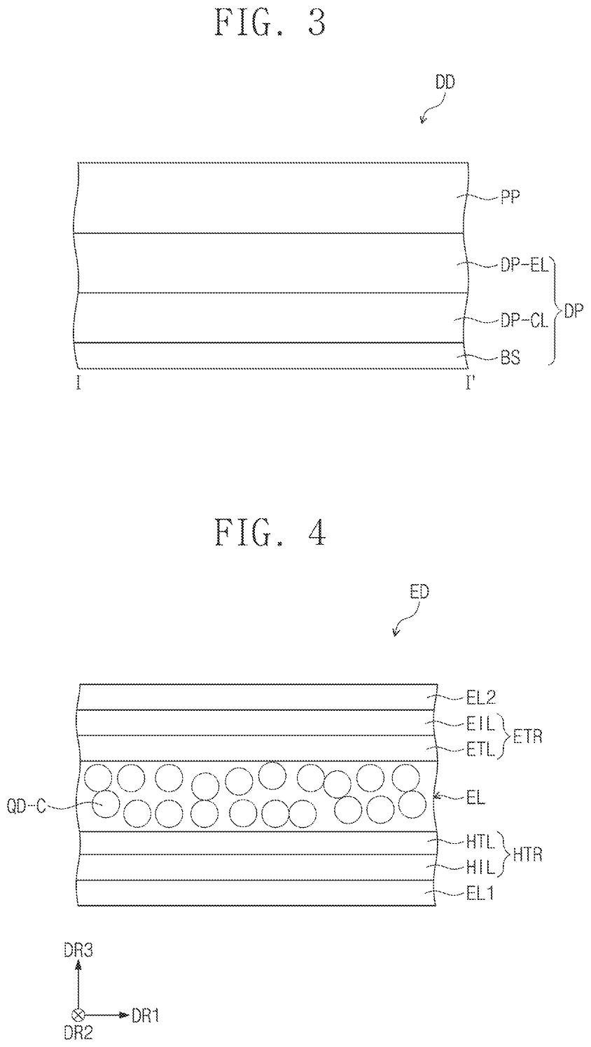

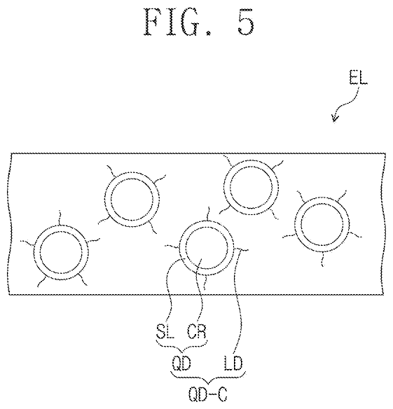

FIG. 1 is a perspective view showing an electronic device EA of an embodiment. FIG. 2 is an exploded perspective view of the electronic device EA of an embodiment. FIG. 3 is a cross-sectional view of a display device DD according to an embodiment. FIG. 4 is a cross-sectional view of a light emitting diode ED of an embodiment, and FIG. 5 is a cross-sectional view showing a portion of a light emitting diode according to an embodiment.

In an embodiment, the electronic device EA may be a large-sized electronic device such as a television set, a monitor, and/or an outdoor billboard. In some embodiments, the electronic device EA may be a small- or medium-sized electronic device such as a personal computer, a laptop computer, a personal digital terminal, a car navigation system, a game console, a smartphone, a tablet, and/or a camera. However, these devices are merely provided as examples, and other electronic devices may be employed as long as not departing from the subject matter of the present disclosure. In the present embodiment, as an example, a smartphone is shown as the electronic device EA.

The electronic device EA may include a display device DD and a housing HAU. The display device DD may display an image IM through a display surface IS. FIG. 1 illustrates that the display surface IS is parallel to a plane defined by a first direction DR1 and a second direction DR2 crossing the first direction DR1. However, this is presented as an example, and in another embodiment, the display surface IS of the display device DD may have a curved shape.

Among the normal direction of (e.g., a direction perpendicular to) display surface IS, that is, the thickness direction of the display device DD, a direction in which the image IM is displayed is indicated by a third direction DR3. A front surface (or an upper surface) and a rear surface (or a lower surface) of respective members may be defined by the third direction DR3.

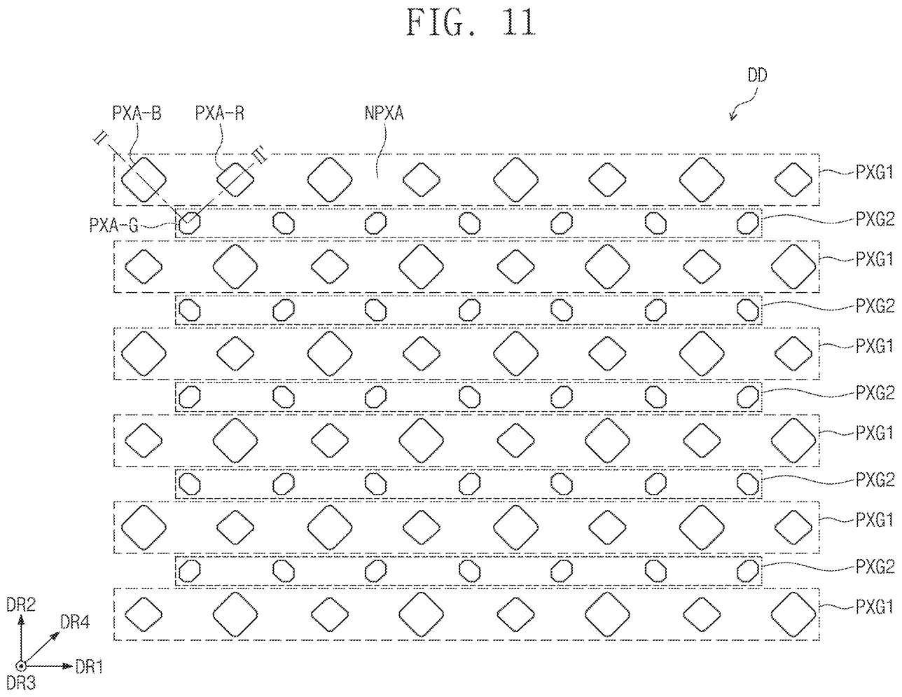

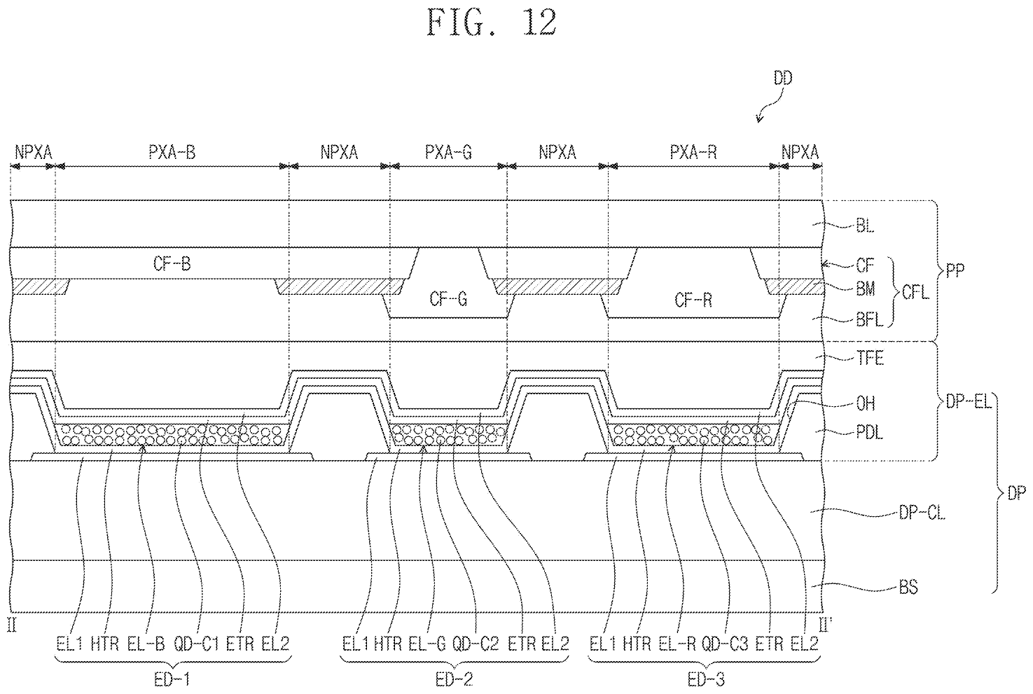

A fourth direction DR4 (see FIG. 11) may be a direction between the first direction DR1 and the second direction DR2. The fourth direction DR4 may be positioned on a plane parallel to the plane defined by the first direction DR1 and the second direction DR2. Meanwhile, the directions indicated by the first to fourth directions DR1, DR2, DR3 and DR4 are relative concepts, and may thus be changed to other directions.

The display surface IS on which the image IM is displayed in the electronic device EA may correspond to a front surface of the display device DD and may correspond to a front surface FS of a window WP. Hereinafter, like reference numerals will be given for the display surface and the front surface of the electronic device EA, and the front surface of the window WP. Accordingly, the front surface of the electronic device EA, the front surface of the display device DD, and the front surface of the window WP will be given the same reference numerals FS. The image IM may include still images as well as dynamic images. In some embodiments, the electronic device EA may include a foldable display device having a folding region and a non-folding region, and/or a bendable display device having at least one bending portion.

The housing HAU may accommodate the display device DD. The housing HAU may be disposed to cover the display device DD while exposing the display surface IS that is a top surface of the display device DD. The housing HAU may cover side surfaces and a bottom surface of the display device DD, and expose an entire top surface. However, the embodiment of the present disclosure is not limited thereto, and the housing HAU may cover a portion of the top surface as well as the side surfaces and the bottom surface of the display device DD.

In the electronic device EA according to an embodiment, the window WP may include an optically transparent insulating material. The window WP may include a transmission region TA and a bezel region BZA. A front surface FS of the window WP including the transmission region TA and the bezel region BZA corresponds to a front surface FS of the electronic device EA. Users may view images provided through the transmission region TA corresponding to the front surface FS of the electronic device EA.

In FIGS. 1 and 2, the transmission region TA is shown in a rectangular shape with rounded corners. However, this is presented as an example, and the transmission region TA may have one or more suitable shapes and is not limited to any one embodiment.

The transmission region TA may be an optically transparent region. The bezel region BZA may be a region having a relatively lower light transmittance than the transmission region TA. The bezel region BZA may have a set or predetermined color. The bezel region BZA may be adjacent to the transmission region TA and surround the transmission region TA. The bezel region BZA may define the shape of the transmission region TA. However, the embodiment of the present disclosure is not limited to what is shown, and the bezel region BZA may be disposed adjacent to only one side of the transmission region TA, and/or a portion thereof may not be provided.

The display device DD may be disposed under the window WP. In the present description, the term “under” may indicate a direction opposite to the direction in which the display device DD provides images.

In an embodiment, the display device DD may be substantially configured to generate an image IM. The image IM generated in the display device DD is displayed on the display surface IS, and is viewed by users through the transmission region TA from the outside. The display device DD includes a display region DA and a non-display region NDA. The display region DA may be a region activated according to electrical signals. The non-display region NDA may be a region covered by the bezel region BZA. The non-display region NDA is adjacent to the display region DA. The non-display region NDA may surround the display region DA.

The display device DD may include a display panel DP and a light control layer PP disposed on the display panel DP. The display panel DP may include a display element layer DP-EL. The display element layer DP-EL includes a light emitting diode ED.

The display device DD may include a plurality of light emitting diodes ED-1, ED-2, and ED-3 (see FIG. 12). The light control layer PP may be disposed on the display panel DP to control reflected light from the display panel DP due to external light, e.g., to control reflection of external light by the display panel DP. The light control layer PP may include, for example, a polarizing layer and/or a color filter layer.

In the display device DD of an embodiment, the display panel DP may be a light emitting display panel. For example, the display panel DP may be a quantum dot light emitting display panel including a quantum dot light emitting diode. However, the embodiment of the present disclosure is not limited thereto.

The display panel DP may include a base substrate BS, a circuit layer DP-CL disposed on the base substrate BS, and a display element layer DP-EL disposed on the circuit layer DP-CL.

The base substrate BS may be a member providing a base surface in which the display element layer DP-EL is disposed. The base substrate BS may be a glass substrate, a metal substrate, a plastic substrate, etc. However, the embodiment of the present disclosure is not limited thereto, and the base substrate BS may be an inorganic layer, an organic layer or a composite material layer. The base substrate BS may be a flexible substrate that may be readily bent and/or folded.

In an embodiment, the circuit layer DP-CL may be disposed on the base substrate BS, and the circuit layer DP-CL may include a plurality of transistors. The transistors each may include a control electrode, an input electrode, and an output electrode. For example, the circuit layer DP-CL may include a switching transistor and a driving transistor to drive the light emitting diode ED of the display element layer DP-EL.

FIG. 4 is a schematic illustration showing a light emitting diode ED according to an embodiment, and referring to FIG. 4, the light emitting diode ED according to an embodiment includes a first electrode EL1, a second electrode EL2 facing the first electrode EL1, and a plurality of functional layers disposed between the first electrode EL1 and the second electrode EL2 and including an emission layer EL.

The plurality of functional layers may include a hole transport region HTR disposed between the first electrode EL1 and the emission layer EL, and an electron transport region ETR disposed between the second electrode EL2 and the emission layer EL. In some embodiments, a capping layer may be further disposed on the second electrode EL2.

The hole transport region HTR and the electron transport region ETR may each include a plurality of sub-functional layers. For example, the hole transport region HTR may include a hole injection layer HIL and/or a hole transport layer HTL as a sub-functional layer, and the electron transport region ETR may include an electron injection layer EIL and/or an electron transport layer ETL as a sub-functional layer. However, the embodiment of the present disclosure is not limited thereto, and the hole transport region HTR may further include an electron blocking layer as a sub-functional layer, and the electron transport region ETR may further include a hole blocking layer as a sub-functional layer.

In the light emitting diode ED according to an embodiment, the first electrode EL1 has conductivity (e.g., is a conductor). The first electrode EL1 may be formed of a metal alloy or a conductive compound. In some embodiments, the first electrode EL1 may be an anode. The first electrode EL1 may be a pixel electrode.

In the light emitting diode ED according to an embodiment, the first electrode EL1 may be a reflective electrode. However, the embodiment of the present disclosure is not limited thereto. For example, the first electrode EL1 may be a transmissive electrode or a transflective electrode. When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, Yb, a compound thereof, or a mixture thereof (e.g., a mixture of Ag and Mg). In some embodiments, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, the first electrode EL1 may be a multilayer metal film, and may have a structure in which metal films of ITO/Ag/ITO are stacked.

The hole transport region HTR is provided on the first electrode EL1. The hole transport region HTR may include a hole injection layer HIL, a hole transport layer HTL, etc. In some embodiments, the hole transport region HTR may further include at least one of a hole buffer layer or an electron blocking layer in addition to the hole injection layer HIL and the hole transport layer HTL. The hole buffer layer may compensate a resonance distance according to the wavelength of light emitted from an emission layer EL, and may thus increase luminous efficiency. Materials which may be included in the hole transport region HTR may be utilized as materials included in the hole buffer layer. The electron blocking layer is a layer that serves to prevent or substantially prevent electrons from being injected from the electron transport region ETR to the hole transport region HTR.

The hole transport region HTR may have a single layer formed of a single material, a single layer formed of a plurality of different materials, or a multilayer structure having a plurality of layers formed of a plurality of different materials. For example, the hole transport region HTR may have a single-layer structure formed of a plurality of different materials, or a structure in which a hole injection layer HIL/hole transport layer HTL, a hole injection layer HIL/hole transport layer HTL/hole buffer layer, a hole injection layer HIL/hole buffer layer, a hole transport layer HTL/hole buffer layer, or a hole injection layer HIL/hole transport layer HTL/electron blocking layer EBL, are stacked in the respective stated order from the first electrode EL1, but the embodiment of the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole injection layer HIL, for example, may include a phthalocyanine compound such as copper phthalocyanine, N,N′-diphenyl-N,N′-bis-[4-(phenyl-m-tolyl-amino)-phenyl]-biphenyl-4,4′-diamine (DNTPD), 4,4′,4″-tris[(3-methylphenyl)phenylamino] triphenylamine (m-MTDATA), 4,4′,4″-tris(N,N-diphenylamino)triphenylamine (TDATA), 4,4′,4″-tris{N,-(2-naphthyl)-N-phenylamino)-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium tetrakis(pentafluorophenyl)borate, dipyrazino[2,3-f: 2′,3′-h]quinoxaline-2,3,6,7,10,11-hexacarbonitrile (HAT-CN), etc.

For example, the hole transport layer HTL may include one or more carbazole-based derivatives (such as N-phenyl carbazole and/or polyvinyl carbazole), fluorine-based derivatives, N,N′-bis(3-methylphenyl)-N,N′-diphenyl-[1,1-biphenyl]-4,4′-diamine (TPD), triphenylamine-based derivatives (such as 4,4′,4″-tris(N-carbazolyl)triphenylamine (TCTA)), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

The emission layer EL is provided on the hole transport region HTR. In the light emitting diode ED according to an embodiment, the emission layer EL may include a quantum dot composite QD-C. The quantum dot composite QD-C included in the emission layer EL may include a quantum dot QD and a ligand LD. The quantum dot composite QD-C may be in a form that the ligand LD is bonded to a surface of the quantum dot QD. The quantum dot composite QD-C may be in a form that the ligand LD having a functional group is bonded to the surface thereof, and may thus have modified surface properties. The quantum dot composite QD-C may be referred to as a surface-modified quantum dot.

The quantum dots QD included in the quantum dot composite QD-C may include a core CR and a shell SL around (e.g., surrounding) the core CR. The ligand LD may be bonded to a surface of the shell SL forming the surface of the quantum dot QD.

The ligand LD bonded to the surface of the quantum dot composite QD-C may include three different ligands (e.g., three different kinds of ligands). The three different ligands may each be bonded to a different binding portion provided on the surface of the quantum dot QD. Hereinafter, the three different ligands included in the quantum dot composite QD-C will be described in more detail later.

In the light emitting diode ED according to an embodiment, the emission layer EL may be formed from a quantum dot composition of an embodiment which will be described in more detail later. The quantum dot composition of an embodiment includes a quantum dot, and a ligand bonded to the quantum dot surface.

The emission layer EL includes a plurality of quantum dot composites QD-C. The quantum dot composites QD-C included in the emission EL may be stacked to form layers (e.g., one or more layers). In FIG. 4, as an example, the quantum dot composites QD-C having a circular cross-section are arranged to form two layers, but the embodiment is not limited thereto. For example, according to the thickness of the emission layer EL, the shape of the quantum dot QD included in the emission layer EL, the average diameter of the quantum dot QD, the type or kind of ligand LD bonded to the surface of the quantum dot QD, and/or the like, the arrangement of the quantum dot composites QD-C may vary. For example, in the emission layer EL, the quantum dot composites QD-C may be arranged adjacent to each other to form a single layer, or a plurality of layers such as two or three layers.

The emission layer EL may have, for example, a thickness of about 5 nm to about 20 nm or about 10 nm to about 20 nm.

In some embodiments, the emission layer EL may have a central emission wavelength of about 500 nm to about 540 nm. The emission layer EL may be to emit green light having a wavelength of about 500 nm to about 540 nm. However, the embodiment of the present disclosure is not limited thereto, and the emission layer EL may be to emit blue light or red light. In some embodiments, the emission layer EL may have a central emission wavelength of about 430 nm to about 490 nm. In some embodiments, the emission layer EL may have a central emission wavelength of about 590 nm to about 650 nm.

As described above, the emission layer EL includes the quantum dot composites QD-C derived from a quantum dot composition of an embodiment. The quantum dot composition may further include a dispersion medium in which the quantum dot composites QD-C are dispersed. The dispersion medium may be, for example, an organic solvent.

In the light emitting diode ED according to an embodiment, the quantum dot composites QD-C included in the emission layer EL are surface-modified by having the ligand LD bonded to the surface of the quantum dot QD. The quantum dot QD included in the emission layer EL of an embodiment may be a semiconductor nanocrystal selected from a Group II-VI compound, a Group III-V compound, a Group III-V compound further containing a Group II element, a Group IV-VI compound, a Group IV element, a Group IV compound, and a combination thereof (e.g., may be AgInS and/or CuInS).

The Group II-VI compound may be selected from the group consisting of a binary compound selected from the group consisting of CdS, CdSe, CdTe, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The Group III-V compound further containing a Group II element may be selected from the group consisting of a ternary compound selected from the group consisting of InZnP, InGaZnP, InAlZnP, and a mixture thereof.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

In this case, the binary compound, the ternary compound, or the quaternary compound may be present in particles in a substantially uniform concentration distribution, or may be present in the same particles in a partially different concentration distribution. In some embodiments, the quantum dot may have a core-shell structure in which one quantum dot is around (e.g., surrounds) another quantum dot. An interface between the core and the shell may have a concentration gradient in which the concentration of an element present in the shell decreases (e.g., becomes lower) towards the center of the core.

In some embodiments, the quantum dot QD may have a core-shell structure including a core CR having nano-crystals, and a shell SL around (e.g., surrounding) the core CR, which is described above. The shell SL of the quantum dot QD having the core-shell structure may serve as a protection layer to prevent or reduce the chemical deformation of the core CR so as to maintain semiconductor properties, and/or as a charging layer to impart electrophoresis properties to the quantum dot QD. The shell SL may be a single layer or multiple layers.

The shell SL may include a different material from the core CR. For example, the core CR may include a first semiconductor nanocrystal, and the shell SL may include a second semiconductor nanocrystal different from the first semiconductor nanocrystal. In some embodiments, the shell SL may include a metal or non-metal oxide. The shell SL may include a metal or non-metal oxide, a semiconductor nanocrystal, or a combination thereof.

The shell SL may be formed of a single material, but may be formed to have a concentration gradient. For example, the shell SL may have a concentration gradient in which the concentration of the second semiconductor nanocrystal present in the shell SL decreases and the concentration of the first semiconductor nanocrystal included in the core CR increases towards the core CR.

For example, the shell SL may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and/or a ternary compound such as MgAl₂O₄, CoFe₂O₄, NiFe₂O₄, and/or CoMn₂O₄. In some embodiments, the shell SL1 may contain CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and/or AlSb.

The quantum dot QD may have a full width of half maximum (FWHM) of a light emission wavelength spectrum of about 45 nm or less, about 40 nm or less, or about 30 nm or less, and color purity and/or color reproducibility may be enhanced in the above ranges. In some embodiments, light emitted through such a quantum dot may be emitted in all directions, and thus a wide viewing angle may be improved.

In some embodiments, the form of the quantum dot QD1 is not particularly limited as long as it is a form commonly utilized in the related art, and for example, a quantum dot in the form of spherical, pyramidal, multi-arm, or cubic nanoparticles, nanotubes, nanowires, nanofibers, nanoplatelets, etc. may be utilized.

The quantum dot QD may control the colors of emitted light according to the particle size thereof, and thus the quantum dot QD may have one or more suitable light emission colors such as blue, red, green, etc. The smaller the particle size of the quantum dot QD becomes, light in the shorter wavelength region may be emitted. For example, in the quantum dot QD having the same core, the particle size of the quantum dot emitting green light may be smaller than the particle size of the quantum dot emitting red light. In some embodiments, in the quantum dot QD having the same core, the particle size of the quantum dot emitting blue light may be smaller than the particle size of the quantum dot emitting green light. However, the embodiment of the present disclosure is not limited thereto, and even in the quantum dot QD having the same core, the particle size may be adjusted according to forming-materials and thickness of a shell.

In some embodiments, when the quantum dots QD have one or more suitable light emission colors such as blue, red, green, etc., the quantum dots QD having different light emission colors may have different core materials.

In some embodiments, in the light emitting diode ED according to an embodiment, the emission layer EL may include a host and a dopant. In an embodiment, the emission layer EL may include the quantum dot QD as a dopant material. In an embodiment, the emission layer EL may further include a host material.

In some embodiments, in the light emitting diode ED according to an embodiment, the emission layer EL may be to emit fluorescent light. For example, the quantum dot QD may be utilized as a fluorescent dopant material.

The emission layer EL may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method. For example, the emission layer EL may be formed by providing the quantum dot composition of an embodiment through inkjet printing.

In the light emitting diode ED of an embodiment, the electron transport region ETR is provided on the emission layer EL. The electron transport region ETR may include at least one among a hole blocking layer, an electron transport layer ETL, and an electron injection layer EIL, but the embodiment of the present disclosure is not limited thereto.

The electron transport region ETR may have a single layer formed of a single material, a single layer formed of a plurality of different materials, or a multilayer structure having a plurality of layers formed of a plurality of different materials.

For example, the electron transport region ETR may have a single layer structure of an electron injection layer EIL or an electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, or a hole blocking layer/electron transport layer ETL/electron injection layer EIL, are stacked in the respective stated order from the emission layer EL, but the present disclosure is not limited thereto. The electron transport region ETR may have a thickness of, for example, about 200 Å to about 1500 Å.

The electron transport region ETR may be formed utilizing one or more suitable methods such as a vacuum deposition method, a spin coating method, a cast method, a Langmuir-Blodgett (LB) method, an inkjet printing method, a laser printing method, a laser induced thermal imaging (LITI) method, etc.

When the electron transport region ETR includes the electron transport layer ETL, the electron transport region ETR may include a metal oxide.

In an embodiment, the metal oxide may include a metal oxide containing at least one among silicon, aluminum, zinc, indium, gallium, yttrium, germanium, scandium, titanium, tantalum, hafnium, zirconium, cerium, molybdenum, nickel, chromium, iron, niobium, tungsten, tin, and copper, or a mixture thereof, but the present disclosure is not limited thereto.

In an embodiment, the metal oxide may include zinc oxide. The type or kind of zinc oxide is not particularly limited, but may be, for example, ZnO, ZnMgO, or a combination thereof, and Li and Y may be utilized for doping the zinc oxide in addition to Mg. In some embodiments, as inorganic materials (e.g., metal oxides) other than zinc oxide, TiO₂, SiO₂, SnO₂, WO₃, Ta₂O₃, BaTiO₃, BaZrO₃, ZrO₂, HfO₂, Al₂O₃, Y₂O₃, ZrSiO₄, etc. may be utilized, but the present disclosure is not limited thereto.

When the electron transport region ETR includes the electron transport layer ETL, the electron transport region ETR may further include a suitable organic material in addition to the metal oxide.

For example, the electron transport region ETR may include an anthracene-based compound. However, the embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), or a mixture thereof. The electron transport layer ETL may have a thickness of about 10 nm to about 100 nm, for example, about 15 nm to about 50 nm. When the thickness of the electron transport layer ETL satisfies the above-described ranges, satisfactory electron transport properties may be obtained without a substantial increase in driving voltage.

When the electron transport region ETR includes the electron injection layer EIL, the electron transport region ETR may include one or more halide metals (e.g., metal halides), metal oxide, lanthanide metals, co-deposition materials of a halide metal (e.g., metal halide) and a lanthanide metal, etc. In some embodiments, the halogenated metal (e.g., metal halides) may be an alkali metal halide. For example, the electron transport region ETR may include LiF, lithium quinolate (Liq), Li₂O, BaO, NaCl, CsF, Yb, RbCl, RbI, KI, CuI, and/or KI: Yb, but the embodiment of the present disclosure is limited thereto. The electron injection layer EIL may also be formed of a mixture of an electron transport material and an insulating organo-metal salt. For example, the organo-metal salt may include, one or more metal acetates, metal benzoates, metal acetoacetates, metal acetylacetonates, and/or metal stearates. The electron injection layer EIL may have a thickness of about 0.1 nm to about 10 nm, for example, about 0.3 nm to about 9 nm. When the thickness of the electron injection layers EIL satisfies the above-described ranges, satisfactory electron injection properties may be obtained without a substantial increase in driving voltage.

As described above, the electron transport region ETR may include a hole blocking layer HBL. The hole blocking layer HBL may include, for example, at least one of 2,9-dimethyl-4,7-diphenyl-1,10-phenanthroline (BCP) or 4,7-diphenyl-1,10-phenanthroline (Bphen), but the embodiment of the present disclosure is not limited thereto.

The second electrode EL2 is provided on the electron transport region ETR. The second electrode EL2 may be a common electrode or a cathode. The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, a compound thereof, or a mixture thereof (e.g., a mixture of Ag and Mg). For example, the second electrode EL2 may include AgMg, AgYb, or MgAg. In some embodiments, the second electrode EL2 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc.

In some embodiments, the second electrode EL2 may be connected with an auxiliary electrode. When the second electrode EL2 is connected with the auxiliary electrode, the resistance of the second electrode EL2 may decrease.

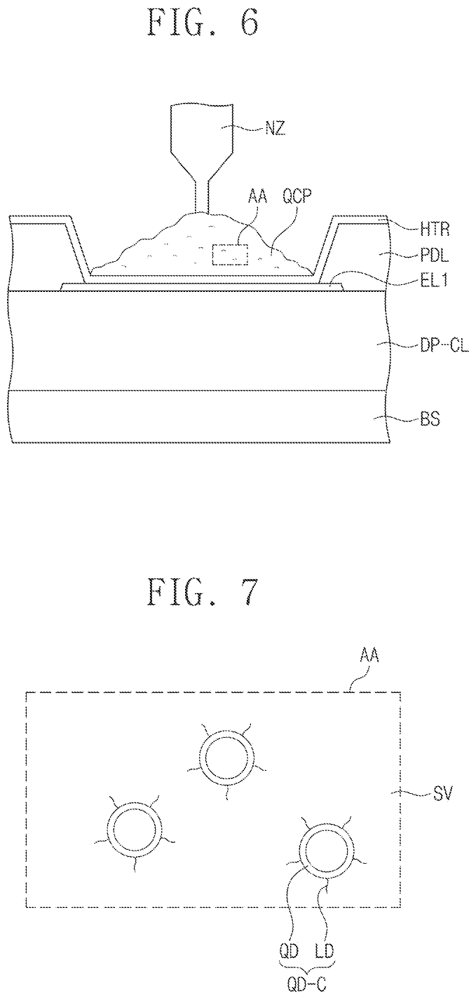

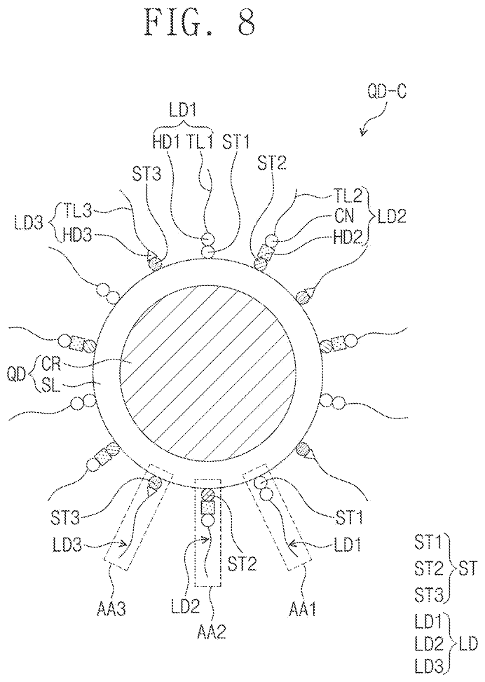

FIG. 6 is a schematic illustration showing one or more processes in a method for manufacturing a light emitting diode according to an embodiment. FIG. 7 is a schematic illustration showing a quantum dot composition according an embodiment. FIG. 8 is a schematic illustration showing a quantum dot and a ligand included in a quantum dot composition of an embodiment.

A method for manufacturing a light emitting diode according to an embodiment may include providing (e.g., depositing or forming) a preliminary emission layer, and providing heat or light to form an emission layer.

FIG. 6 is a schematic illustration showing forming an emission layer in a method for manufacturing a light emitting diode according to an embodiment. The forming of the emission layer may include providing a quantum dot composition QCP on a hole transport region HTR. The quantum dot composition QCP may be provided between pixel defining films PDL through a nozzle NZ.

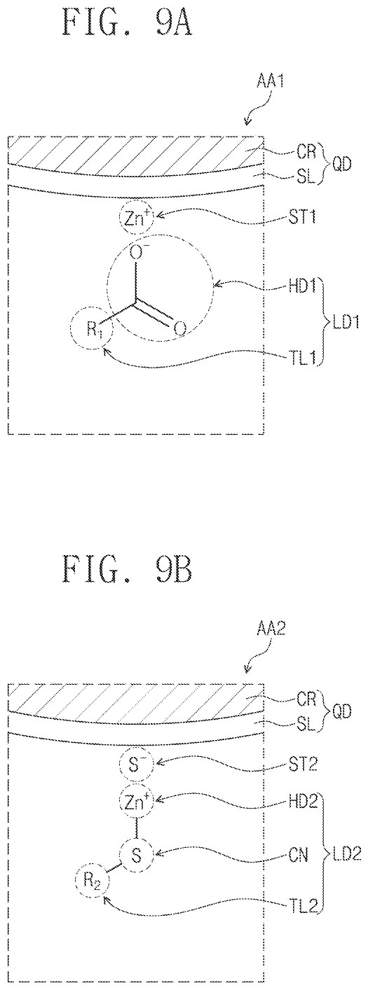

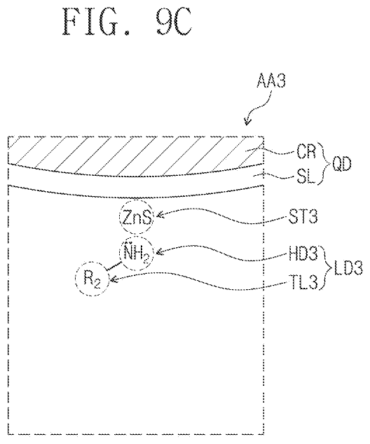

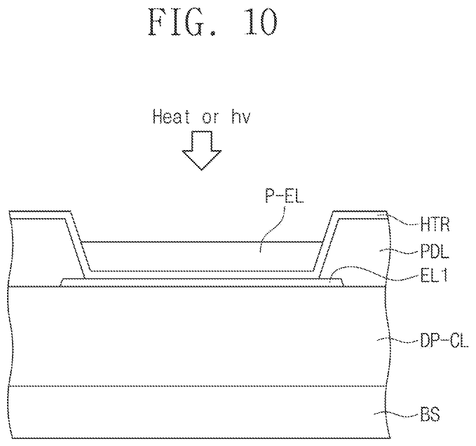

FIG. 7 is a schematic illustration showing in more detail a portion (region “AA”) of the quantum dot composition QCP provided in FIG. 6. FIG. 8 is a schematic illustration showing a quantum dot composite QD-C including a quantum dot QD and a ligand LD bonded to a surface of the quantum dot QD. FIGS. 9A-9C are schematic illustrations showing a form in which a ligand LD included in a quantum dot composition QCP according to an embodiment is bonded to a surface of the quantum dot QD.

Referring to FIGS. 6 to 8, the quantum dot composition QCP of an embodiment may include a quantum dot composite QD-C having a quantum dot QD and a ligand LD bonded to a surface of the quantum dot QD. The quantum dot composition QCP may further include an organic solvent SV in which the quantum dot composites QD-C including the quantum dot QD and the ligand LD are dispersed. The organic solvent SV may be a non-polar organic solvent. For example, the organic solvent SV may include hexane, toluene, chloroform, dimethyl sulfoxide, and/or dimethyl formamide. However, the embodiment of the present disclosure is not limited thereto.

The quantum dot composites QD-C may be dispersed in the organic solvent SV and provided. When the ligand LD is bonded to the surface of the quantum dot QD, the quantum dot composites QD-C in the organic solvent SV may have increased dispersibility. In the forming of the emission layer, evaporating the organic solvent SV by applying heat and/or light after the providing of the quantum dot composition QCP may be further included.

As described above, the quantum dot QD may include the core CR and the shell SL around (e.g., surrounding) the core CR. However, the embodiment is not limited thereto, and the quantum dots QD may have a single layer structure or may have a plurality of shells. In some embodiments, the descriptions of the quantum dot composites QD-C described in the light emitting diode ED of an embodiment described with reference to FIGS. 4 and 5 may be equally applied to the quantum dot composites QD-C included in the quantum dot composition QCP of an embodiment.

Referring to FIG. 8, the ligand LD includes a first ligand LD1, a second ligand LD2, and a third ligand LD3. The first ligand LD1, the second ligand LD2, and the third ligand LD3 may each be bonded to different binding portions ST provided on the surface of the quantum dot QD. In an embodiment, the shell SL of the quantum dot QD is provided with a plurality of binding portions ST. The plurality of binding portions ST may include a first binding portion ST1, a second binding portion ST2, and a third binding portion ST3. The first ligand LD1 may be bonded to the first binding portion ST1, the second ligand LD2 may be bonded to the second binding portion ST2, and the third ligand LD3 may be bonded to the third binding portion ST3.

The first ligand LD1, the second ligand LD2, and the third ligand LD3 may each include a head portion bonded to a respective one of the plurality of binding portions ST provided in the shell SL. The first ligand LD1 may include a first head portion HD1 bonded to the first binding portion ST1, the second ligand LD2 may include a second head portion HD2 bonded to the second binding portion ST2, and the third ligand LD3 may include a third head portion HD3 bonded to the third binding portion ST3. In the present description, the first head portion HD1 may be (e.g., may be referred to as) an electron-donating head portion, the second head portion HD2 may be (e.g., may be referred to as) an electron-withdrawing head portion, and the third head portion HD3 may be (e.g., may be referred to as) a coordination-binding head portion.

At least one of the first ligand, the second ligand, or the third ligand may further include a tail portion. The tail portion may be a portion for increasing dispersibility when the ligands LD are dispersed in the organic solvent SV. As shown in FIG. 8, the first ligand LD1, the second ligand LD2, and the third ligand LD3 may all include the tail portion. The first ligand LD1 may include a first tail portion TL1, the second ligand LD2 may include a second tail portion TL2, and the third ligand LD3 may include a third tail portion TL3. The first tail portion TL1 may be connected to the first head portion HD1, and the third tail portion TL3 may be connected to the third head portion HD3. However, the embodiment of the present disclosure is not limited thereto, and the first tail portion TL1 may not be provided. In an embodiment, the first tail portion TL1 may not be provided, and the first ligand LD1 may include only the first head portion HD1.

The second ligand LD2 may further include a connection portion CN. The second ligand LD2 may include the second head portion HD2, the connection portion CN, and the second tail portion TL2, the connection portion CN may be connected to the second head portion HD2, and the second tail portion TL2 may be connected to the connection portion CN.

FIGS. 9A to 9C are schematic illustrations showing a form in which a ligand LD included in a quantum dot composition QCP according to an embodiment is bonded to a surface of the quantum dot QD. FIG. 9A is an enlarged view of portion AA1 of FIG. 8, that is, the portion where a first ligand LD1 is bonded to a quantum dot QD, FIG. 9B is an enlarged view of portion AA2 of FIG. 8, that is, the portion where a second ligand LD2 is bonded to a quantum dot QD, and FIG. 9C is an enlarged view of portion AA3 of FIG. 8, that is, the portion where a third ligand LD3 is bonded to a quantum dot QD.

Referring to FIGS. 8 and 9A to 9C together, the plurality of binding portions ST provided on the surface of the shell SL of the quantum dot QD may be defective portions exposed on the surface of semiconductor nanocrystals included in the shell SL. The plurality of binding portions ST, unlike atoms present in a fully crystalline state inside the shell SL, may be in a state of having some bonds broken on the surface of the shell SL due to coordination unsaturation, that is, a dangling bond. In an embodiment, the shell SL may include a Group II-VI compound, a Group III-V compound, a Group IV-VI compound, and/or the like, and each of the Group II, III, IV, V, and VI elements included in the shell SL may be exposed in the state of coordination unsaturation, or may be bonded to a corresponding element, but exposed in the state of coordination unsaturation to provide the plurality of binding portions ST. The plurality of binding portions ST included in the shell SL may include a first binding portion ST1 in which cations are exposed, a second binding portion ST2 in which anions are exposed, and a third binding portion ST3 in which cations and anions are bonded to each other and exposed.

Referring to FIG. 9A, the first ligand LD1 may be bonded to the first binding portion ST1, and the first binding portion ST1 may be a defective portion in which cations are exposed. FIG. 9A shows that the shell SL includes ZnS, and the first binding portion ST1 is a Zn cation (e.g., Zn⁺) as an example. However, the embodiment of the present disclosure is not limited thereto, and the first binding portion ST1 may be at least one selected from a Zn cation, a Cd cation, a Hg cation, a Mg cation, a Ag cation, a Cu cation, a Ga cation, an Al cation, an In cation, a Sn cation, and a Pb cation.

The first ligand LD1 may include a first head portion HD1 bonded to the first binding portion ST1, and a first tail portion TL1 bonded to the first head portion HD1. In an embodiment, the first head portion HD1 may include an electron-donating functional group to be bonded to the first binding portion ST1, which is a cation-exposed defective portion.

The first head portion HD1 may be referred to as an electron-donating head portion. The first head portion HD1 may have a structure including anions in a functional group. FIG. 9A shows that the first head portion HD1 includes carboxylate as an example. However, the embodiment of the present disclosure is not limited thereto, and the first head portion may be any one among halide ions, carboxylate, phosphinate, phosphonate, phosphonic acid anhydride, alkoxylate, dithiolate, and thiolate. When the first head portion HD1 is halide ions, the first tail portion TL1 may not be provided. For example, when the first head portion HD1 is halide ions, the first ligand LD1 may include only the first head portion HD1.

The first tail portion may include a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms. For example, the first tail portion TL1 may be a substituted or unsubstituted ethyl group, a substituted or unsubstituted octyl group, a substituted or unsubstituted dodecyl group, or a substituted or unsubstituted phenyl group.

In the present description, the term “substituted or unsubstituted” may indicate that one (e.g., a functional group) is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkoxy group, a hydrocarbon ring group, an aryl group, and a heterocyclic group. In some embodiments, each of the substituents exemplified above may be further substituted or unsubstituted. For example, a biphenyl group may be interpreted as an aryl group or as a phenyl group substituted with a phenyl group.

Referring to FIG. 9B, the second ligand LD2 may be bonded to the second binding portion ST2, and the second binding portion ST2 may be a defective portion in which anions are exposed. FIG. 9B shows that the shell SL includes ZnS, and the second binding portion ST2 is a S anion (e.g., S⁻) as an example. However, the embodiment of the present disclosure is not limited thereto, and the first binding portion ST1 may be at least one selected from a S anion, a Se anion, a Te anion, a N anion, a P anion, an As anion, and a Sb anion.

The second ligand LD2 may include a second head portion HD2 bonded to the second binding portion ST2, a connection portion CN connected to the second head portion HD2, and the second tail portion TL2 connected to the connection portion CN. In an embodiment, the second head portion HD2 may include an electron-withdrawing functional group to be bonded to the second binding portion ST2, which is an anion-exposed defective portion.

The second head portion HD2 may be referred to as an electron-withdrawing head portion. The second head portion HD2 may have a structure including cations in a functional group. The second head portion HD2 may include metal atoms. FIG. 9B shows that the second head portion HD2 includes Zn atoms as an example. However, the embodiment of the present disclosure is not limited thereto, and the second head portion HD2 may be any one metal atom among Mg, Ca, Sc, Sn, Ti, V, Cr, Mn, Fe, Co, Ni, Cu, Zn, Ga, Sr, Y, Zr, Nb, Mo, Cd, In, Ba, Au, Hg, and Tl.

The second tail portion TL2 may include a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms. For example, the second tail portion TL2 may be a substituted or unsubstituted ethyl group, a substituted or unsubstituted octyl group, a substituted or unsubstituted dodecyl group, or a substituted or unsubstituted phenyl group.

The connection portion CN may connect the second head portion HD2 including metal atoms with the second tail portion TL2. The connection portion CN may include, for example, carboxylate, phosphinate, phosphonate, phosphonic acid anhydride, alkoxylate, dithiolate, and/or thiolate.

Referring to FIG. 9C, the third ligand LD3 may be bonded to the third binding portion ST3, and the third binding portion ST3 may be a defective portion exposed in a state of having cations and anions bonded to each other. For example, the third binding portion ST3 may be a defective portion in which cations and anions included in the shell SL are bonded to form a crystal, but some bonds are broken due to coordination unsaturation and exposed. FIG. 9C shows that the shell SL includes ZnS, and the third binding portion ST3 is a ZnS crystal as an example. However, the embodiment of the present disclosure is not limited thereto, and the third binding portion ST3 may be selected from compounds forming semiconductor nanocrystals included in the quantum dot QD, that is, the Group II-VI compound, the Group III-V compound, and/or the Group IV-VI compound described above.

The third ligand LD3 may include a third head portion HD3 bonded to the third binding portion ST3, and a third tail portion TL3 bonded to the third head portion HD3. In an embodiment, the third head portion HD3 may include a coordination-binding functional group to be bonded to the third binding portion ST3, which is a defective portion exposed in a state of having cations and anions bonded to each other.

The third head portion HD3 may be referred to as a coordination-binding head portion. The third head portion HD3 may have a structure including non-covalent electron pairs for coordination-binding in a functional group. FIG. 9C shows that the third head portion HD3 includes a first amine group containing non-covalent electron pairs as an example. However, the embodiment of the present disclosure is not limited thereto, and the third head portion HD3 may be any one selected from primary or secondary amine, phosphine, phosphine oxide, imidazole, and pyridine.

The third tail portion TL3 may include a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms. For example, the third tail portion TL3 may be a substituted or unsubstituted ethyl group, a substituted or unsubstituted octyl group, a substituted or unsubstituted dodecyl group, or a substituted or unsubstituted phenyl group.

In the quantum dot composite QD-C according to an embodiment, the first ligand LD1 may be represented by Formula 1-1 or Formula 1-2.

A₁-R₁. Formula 1-1

In Formula 1-1, A₁ is any one among carboxylate, phosphinate, phosphonate, phosphonic acid anhydride, alkoxylate, dithiolate, and thiolate. For example, A₁ may be carboxylate.

In Formula 1-1, R₁ is a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms. For example, R₁ may be a substituted or unsubstituted ethyl group, a substituted or unsubstituted octyl group, a substituted or unsubstituted dodecyl group, or a substituted or unsubstituted phenyl group.

A₂. Formula 1-2

In Formula 1-2, A₂ is a halide ion. For example, A₂ may be a chloride ion (Cl⁻) or a bromide ion (Br⁻).

In the quantum dot composite QD-C according to an embodiment, the second ligand LD2 may be represented by Formula 2.

M-A₃-R₂. Formula 2

In Formula 2, M is any one metal atom among Mg, Ca, Sc, Sn, Ti, V, Cr, Mn, Fe, Co, Ni, Cu, Zn, Ga, Sr, Y, Zr, Nb, Mo, Cd, In, Ba, Au, Hg, and Tl. For example, M may be Zn or Mg.

In Formula 2, A₃ is any one among carboxylate, phosphinate, phosphonate, phosphonic acid anhydride, alkoxylate, dithiolate, and thiolate. For example, A₃ may be thiolate.

In Formula 2, R₂ is a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms. For example, R₂ may be a substituted or unsubstituted ethyl group, a substituted or unsubstituted octyl group, a substituted or unsubstituted dodecyl group, or a substituted or unsubstituted phenyl group.

In the quantum dot composite QD-C according to an embodiment, the third ligand LD3 may be represented by Formula 3.

A₄-R₃. Formula 3

In Formula 3, A₄ is any one among phosphine, phosphine oxide, amine, imidazole, and pyridine. For example, A₄ may be primary or secondary amine, or phosphine.

In Formula 3, R₃ is a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms. For example, R₃ may be a substituted or unsubstituted ethyl group, a substituted or unsubstituted octyl group, a substituted or unsubstituted dodecyl group, or a substituted or unsubstituted phenyl group.

FIG. 10 is a schematic illustration showing a portion of a method for manufacturing a light emitting diode according to an embodiment.

FIG. 10 is a schematic illustration showing forming an emission layer by providing heat or light (e.g., hv) in a method for manufacturing a light emitting diode according to an embodiment. FIG. 10 shows providing heat or hv to a preliminary emission layer P-EL. The providing of heat to the preliminary emission layer P-EL may be baking by providing heat at 50° C. or higher to the preliminary emission layer P-EL. The baking may be to remove an organic solvent SV and/or the like included in a quantum dot composition QCP. For example, the providing of heat to the preliminary emission layer P-EL removes the organic solvent SV included in the preliminary emission layer P-EL by providing heat at 100° C. or higher. In some embodiments, the forming of the emission layer may be by removing the organic solvent SV included in the preliminary emission layer P-EL by providing UV to the preliminary emission layer P-EL.

FIG. 11 is a plan view showing a display device DD according to an embodiment. FIG. 12 is a cross-sectional view showing a display device DD of an embodiment. FIG. 12 is a cross-sectional view corresponding to the line II-II′ of FIG. 11.

Referring to FIGS. 11 and 12, the display device DD of an embodiment may include a plurality of light emitting diodes ED-1, ED-2, and ED-3, and the light emitting diodes ED-1, ED-2, and ED-3 include emission layers EL-B, EL-G, and EL-R having quantum dot composites QD-C1, QD-C2, and QD-C3 respectively.

In some embodiments, the display device DD according to an embodiment may include a display panel DP having a plurality of light emitting diodes ED-1, ED-2, and ED-3 and a light control layer PP disposed on the display panel DP. In some embodiments, unlike what is shown in the drawings, the light control layer PP may not be provided in the display device DD of an embodiment.

The display panel DP may include a base substrate BS, a circuit layer DP-CL and a display element layer DP-EL provided on the base substrate BS, and the display element layer DP-EL may include pixel defining films PDL, light emitting diodes ED-1, ED-2 and ED-3 disposed between the pixel defining films PDL, and an encapsulation layer TFE disposed on the light emitting diodes ED-1, ED-2 and ED-3.

The display device DD may include non-light emitting regions NPXA and light emitting regions PXA-B, PXA-G, and PXA-R. The light emitting regions PXA-B, PXA-G, and PXA-R may each be a region emitting light generated from a corresponding one of the light emitting diodes ED-1, ED-2, and ED-3. The light emitting regions PXA-B, PXA-G, and PXA-R may be spaced apart from one another on a plane.

The light emitting regions PXA-B, PXA-G, and PXA-R may be divided into a plurality of groups according to the color of light generated from the light emitting diodes ED-1, ED-2, and ED-3. In the display device DD of an embodiment shown in FIGS. 11 and 12, three light emitting regions PXA-B, PXA-G, and PXA-R, which emit blue light, green light, and red light, respectively, are illustrated as an example. For example, the display device DD of an embodiment may include a blue light emitting region PXA-B, a green light emitting region PXA-G, and a red light emitting region PXA-R, which are distinct from one another.

The plurality of light emitting diodes ED-1, ED-2, and ED-3 may be to emit light having different wavelength ranges. For example, in an embodiment, the display device DD may include a first light emitting diode ED-1 emitting blue light, a second light emitting diode ED-2 emitting green light, and a third light emitting diode ED-3 emitting red light. However, the embodiment of the present disclosure is not limited thereto, and the first to third light emitting diodes ED-1, ED-2 and ED-3 may be to emit light in substantially the same wavelength range or emit light in at least one different wavelength range.

For example, the blue light emitting region PXA-B, the green light emitting region PXA-G, and the red light emitting region PXA-R of the display device DD may correspond to the first light emitting diode ED-1, the second light emitting diode ED-2, and the third light emitting diode ED-3, respectively.

The first emission layer EL-B of the first light emitting diode ED-1 may include a first quantum dot composite QD-C1. The first quantum dot composite QD-C1 may be to emit blue light as a first light. The second emission layer EL-G of the second light emitting diode ED-2 and the third emission layer EL-R of the third light emitting diode ED-3 may include a second quantum dot composite QD-C2 and a third quantum dot composite QD-C3, respectively. The second quantum dot composite QD-C2 and the third quantum dot composite QD-C3 may be to emit green light as a second light and red light as a third light, respectively.

The first to third quantum dot composites QD-C1, QD-C2, and QD-C3 may each include quantum dots and three different ligands (e.g., three different kinds of ligands) bonded to the surfaces of the quantum dots. The descriptions of the quantum dot composite QD-C described in the light emitting diode of an embodiment and in the quantum dot composition of an embodiment above may be equally applied to each of the first to third quantum dot composites QD-C1, QD-C2, and QD-C3.

Each of the first to third emission layers EL-B, EL-G, and EL-R including a respective one of the first to third quantum dot composites QD-C1, QD-C2, and QD-C3 may be derived from a quantum dot composition including a quantum dot and a ligand bonded to the surface of the quantum dot. The first to third emission layers EL-B, EL-G, and EL-R may each include a respective one of the first to third quantum dot composites QD-C1, QD-C2, and QD-C3 including first to third ligands bonded to each of a cation-exposed binding portion, an anion-exposed binding portion, and the cation-anion-exposed binding portions provided on the surface of the quantum dot, respectively.

In an embodiment, the first to third quantum dot composites QD-C1, QD-C2, and QD-C3 included in the light emitting diodes ED-1, ED-2, and ED-3 may be formed of different core materials. In some embodiments, the first to third quantum dot composites QD-C1, QD-C2, and QD-C3 may be formed of the same core material, or two quantum dots selected from the first to third quantum dot composites QD-C1, QD-C2, and QD-C3 may be formed of the same core material, and the rest may be formed of different core materials.

In an embodiment, the first to third quantum dot composites QD-C1, QD-C2, and QD-C3 may have different diameters. For example, the first quantum dot composite QD-C1 utilized in the first light emitting diode ED-1 emitting light in a relatively shorter wavelength range may have a relatively smaller average diameter than the second quantum dot composite QD-C2 of the second light emitting diode ED-2 and the third quantum dot composite QD-C3 of the third light emitting diode ED-3, each emitting light in a relatively longer wavelength region. In the present description, the average diameter refers to the arithmetic mean of the diameters of a plurality of quantum dot particles. In some embodiments, the diameter of the quantum dot particle may be the average value of the width of the quantum dot particle in a cross section.

In the display device DD of an embodiment, as shown in FIGS. 11 and 12, an area of each of the light emitting regions PXA-B, PXA-G and PXA-R may be different in size from one another. In this case, the area may refer to an area when viewed on a plane defined by the first direction DR1 and the second direction DR2.

The light emitting regions PXA-B, PXA-G and PXA-R may have different areas in size according to the color emitted from the emission layers EL-B, EL-G and EL-R of the light emitting diodes ED-1, ED-2 and ED-3. For example, referring to FIGS. 11 and 12, the blue light emitting region PXA-B corresponding to the first light emitting diode ED-1 emitting blue light may have the largest area, and the green light emitting region PXA-G corresponding to the second light emitting diode ED-2 generating green light may have the smallest area in the display device DD of an embodiment. However, the embodiment of the present disclosure is not limited thereto, and the light emitting regions PXA-B, PXA-G and PXA-R may be to emit light other than blue light, green light and red light, or the light emitting regions PXA-B, PXA-G and PXA-R may have the same size of area, or the light emitting regions PXA-B, PXA-G, and PXA-R may be provided at different area ratios from those shown in FIG. 11.

The light emitting regions PXA-R, PXA-G, and PXA-B may each be a region separated by the pixel defining films PDL. The non-light emitting regions NPXA may be regions between neighboring light emitting regions PXA-B, PXA-G and PXA-R, and may correspond to the pixel defining films PDL. In some embodiments, each of the light emitting regions PXA-B, PXA-G and PXA-R may correspond to a pixel. The pixel defining films PDL may separate the light emitting diodes ED-1, ED-2 and ED-3. The emission layers EL-B, EL-G and EL-R of the light emitting diodes ED-1, ED-2 and ED-3 may be disposed and separated in openings OH defined by the pixel defining films PDL.

The pixel defining films PDL may be formed of a polymer resin. For example, the pixel defining films PDL may be formed from a material including a polyacrylate-based resin or a polyimide-based resin. In some embodiments, the pixel defining films PDL may be formed by further including an inorganic material in addition to the polymer resin. In some embodiments, the pixel defining films PDL may be formed from a material including a light absorbing material, or may be formed from a material including a black pigment and/or a black dye. The pixel defining films PDL formed from a material including a black pigment and/or a black dye may implement a black pixel defining film. When forming the pixel defining films PDL, carbon black may be utilized as a black pigment and/or a black dye, but the embodiment of the present disclosure is not limited thereto.

In some embodiments, the pixel defining films PDL may be formed of an inorganic material. For example, the pixel defining films PDL may be formed from a material including silicon nitride (SiNx), silicon oxide (SiOx), silicon oxide (SiOxNy), etc. The pixel defining films PDL may define light emitting regions PXA-B, PXA-G, and PXA-R. The light emitting regions PXA-B, PXA-G, and PXA-R, and the non-light emitting regions NPXA may be separated by the pixel defining films PDL.

The light emitting diodes ED-1, ED-2, and ED-3 may each include a first electrode EL1, a hole transport region HTR, an emission layer EL-R, EL-G, or EL-B, an electron transport region ETR, and a second electrode EL2. In the light emitting diodes ED-1, ED-2, and ED-3 included in the display device DD according to an embodiment, except that the quantum dot composites QD-C1, QD-C2, and QD-C3 included in the emission layers EL-B, EL-G, and EL-R are different from each other, the same description in connection with FIG. 4 and/or the like may be equally applied to the first electrode EL1, the hole transport region HTR, the electron transport region ETR, and the second electrode EL2.

An encapsulation layer TFE may cover the light emitting diodes ED-1, ED-2 and ED-3. The encapsulation layer TFE may be a single layer or a laminated layer of a plurality of layers. The encapsulation layer TFE may be a thin film encapsulation layer. The encapsulation layer TFE protects the light emitting diodes ED-1, ED-2 and ED-3. The encapsulation layer TFE may cover an upper surface of the second electrode EL2 disposed in the openings OH, and may fill the openings OH.

FIG. 12 illustrates that the hole transport region HTR and the electron transport region ETR are provided as a common layer while covering the pixel defining films PDL, but the embodiment of the present disclosure is not limited thereto. In an embodiment, the hole transport region HTR and the electron transport region ETR may be disposed in the openings OH defined in the pixel defining films PDL.

For example, when in addition to the emission layers EL-B, EL-G, and EL-R, the hole transport region HTR and the electron transport region ETR are provided through inkjet printing, the hole transport region HTR, the emission layer EL-B, EL-G, and EL-R, and the electron transport region ETR may each be provided corresponding to the openings OH defined between the pixel defining films PDL. However, the embodiment of the present disclosure is not limited thereto, and, regardless of the method of providing each functional layer, as shown in FIG. 12, the hole transport region HTR and the electron transport region ETR may be provided as a common layer while covering the pixel defining films PDL without being patterned.

In the display device DD of an embodiment illustrated in FIG. 12, although the thicknesses of the emission layers EL-B, EL-G, and EL-R of the first to third light emitting diodes ED-1, ED-2, and ED-3 are illustrated to be similar to one another, the embodiment of the present disclosure is not limited thereto. For example, in an embodiment, the thicknesses of the emission layers EL-B, EL-G, and EL-R of the first to third light emitting diodes ED-1, ED-2, and ED-3 may be different from one another.

Referring to FIG. 11, the blue light emitting regions PXA-B and the red light emitting regions PXA-R may be alternately arranged in the first direction DR1 to form a first group PXG1. The green light emitting regions PXA-G may be arranged in the first direction DR1 to form a second group PXG2.

The first group PXG1 and the second group PXG2 may be spaced apart along the second direction DR2. Each of the first group PXG1 and the second group PXG2 may be provided in plurality. The first groups PXG1 and the second groups PXG2 may be alternately arranged in the second direction DR2.

One green light emitting region PXA-G may be disposed spaced apart from one blue light emitting region PXA-B or one red light emitting region PXA-R in the fourth direction DR4. The fourth direction DR4 may be a direction between the first direction DR1 and the second direction DR2.

The arrangement structure of the light emitting regions PXA-B, PXA-G and PXA-R shown in FIG. 11 may be referred to as a Pentile® structure. However, the arrangement structure of the light emitting regions PXA-B, PXA-G and PXA-R in the display device DD according to an embodiment is not limited to the arrangement structure shown in FIG. 11. For example, in an embodiment, the light emitting regions PXA-B, PXA-G and PXA-R may have a stripe structure in which the blue light emitting region PXA-B, the green light emitting region PXA-G, and the red light emitting region PXA-R may be alternately arranged along the first direction DR1.

Referring to FIGS. 3 and 12, the display device DD of an embodiment may further include a light control layer PP. The light control layer PP may block or reduce external light incident to the display panel DP from outside the display device DD, e.g., to control reflection of external light by the display panel DP. The light control layer PP may block or reduce part of the external light. The light control layer PP may perform a reflection preventing or reducing function minimizing or reducing reflection due to external light.

In an embodiment illustrated in FIG. 12, the light control layer PP may include a color filter layer CFL. For example, the display device DD of an embodiment may further include the color filter layer CFL disposed on the light emitting diodes ED-1, ED-2, and ED-3 of the display panel DP.

In the display device DD of an embodiment, the light control layer PP may include a base layer BL and a color filter layer CFL.

The base layer BL may be a member providing a base surface on which the color filter layer CFL is disposed. The base layer BL may be a glass substrate, a metal substrate, a plastic substrate, etc. However, the embodiment of the present disclosure is not limited thereto, and the base layer BL may be an inorganic layer, an organic layer, or a composite material layer.

The color filter layer CFL may include a light blocking unit BM and a color filter unit CF. The color filter unit CF may include a plurality of filters CF-B, CF-G, and CF-R. For example, the color filter layer CFL may include a first filter CF-B transmitting a first color light, a second filter CF-G transmitting a second color light, and a third filter CF-R transmitting a third color light. For example, the first filter CF-B may be a blue filter, the second filter CF-G may be a green filter, and the third filter CF-R may be a red filter.

Each of the filters CF-B, CF-G, and CF-R may include a polymer photosensitive resin and a pigment and/or a dye. The first filter CF-B may include a blue pigment and/or a blue dye, the second filter CF-G may include a green pigment and/or a green dye, and the third filter CF-R may include a red pigment and/or a red dye.

However, the embodiment of the present disclosure is not limited thereto, and the first filter CF-B may not include (e.g., may exclude) a pigment or a dye. The first filter CF-B may include a polymer photosensitive resin, but not include a pigment or a dye. In some embodiments, the first filter CF-B may be transparent. The first filter CF-B may be formed of a transparent photosensitive resin.

The light blocking unit BM may be a black matrix. The light blocking unit BM may be formed from a material including an organic light blocking material or an inorganic light blocking material, each including a black pigment and/or a black dye. The light blocking unit BM may prevent or reduce light leakage, and separate boundaries between the adjacent filters CF-B, CF-G, and CF-R.

The color filter layer CFL may further include a buffer layer BFL. For example, the buffer layer BFL may be a protection layer protecting the filters CF-B, CF-G, and CF-R. The buffer layer BFL may be an inorganic material layer including at least one inorganic material among silicon nitride, silicon oxide, and silicon oxynitride. The buffer layer BFL may be formed of a single layer or a plurality of layers.

In an embodiment shown in FIG. 12, the first filter CF-B of the color filter layer CFL is illustrated to overlap the second filter CF-G and the third filter CF-R, but the embodiment of the present disclosure is not limited thereto. For example, the first to third filters CF-B, CF-G and CF-R may be separated by the light blocking unit BM and may not overlap one another. In an embodiment, each of the first to third filters CF-B, CF-G and CF-R may be disposed corresponding to the blue light emitting region PXA-B, green light emitting region PXA-G, and red light emitting region PXA-R, respectively.

Unlike what is shown in FIG. 12, the display device DD of an embodiment may include a polarizing layer as a light control layer PP instead of the color filter layer CFL. The polarizing layer may block or reduce external light provided to the display panel DP from the outside. The polarizing layer may block or reduce part of the external light.

In some embodiments, the polarizing layer may reduce reflected light generated in the display panel DP by external light. That is, the polarizing layer may reduce reflection of external light by the display panel DP. For example, the polarizing layer may function to block or reduce reflected light in a case where light provided from outside the display device DD is incident to the display panel DP and exits again. The polarizing layer may be a circularly polarizer having an anti-reflection (or a reflection preventing or reducing) function or the polarizing layer may include a linear polarizer and a λ/4 phase retarder. In some embodiments, the polarizing layer may be disposed on the base layer BL to be exposed (e.g., to the outside) or the polarizing layer may be disposed under the base layer BL.

The display device according to an embodiment includes a quantum dot composite in which three different ligands (e.g., three different kinds of ligands) are bonded to a surface of a quantum dot in an emission layer, and thus the surface defects of the quantum dot are passivated through the ligands, thereby exhibiting excellent or suitable luminous efficiency. The surface of the quantum dot including semiconductor nanocrystals may be provided with three different defective portions (three different kinds of defective portions), such as a cation-exposed defect, an anion-exposed defect, and/or a cation-anion-exposed defect, and when the quantum dot having surface defect(s) is applied to the emission layer of a light emitting diode, electron and hole traps may occur due to the surface defects, thereby reducing the luminous efficiency of the light emitting diode. The quantum dot composite of an embodiment of the present disclosure is provided with three different ligands each bonded to a respective one among the cation-exposed defect, the anion-exposed defect, and the cation-anion-exposed defect, and thus, the surface defects of the quantum dot may all be passivated through the three different ligands. Accordingly, when the quantum dot composite is applied to the emission layer of the light emitting diode, excellent or suitable luminous efficiency characteristics may be achieved.

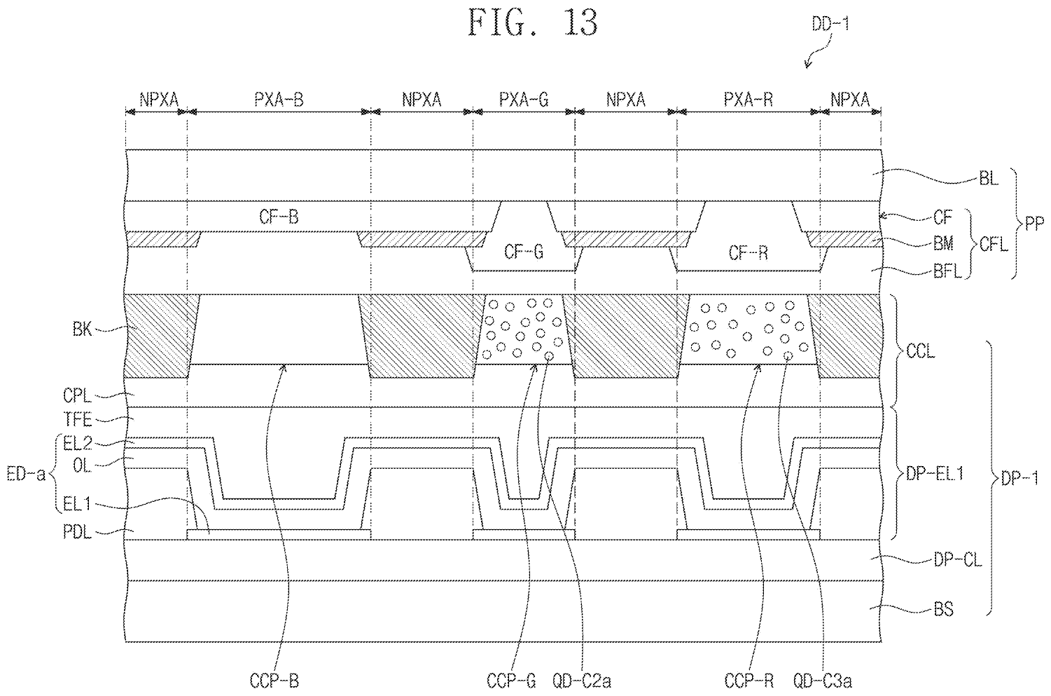

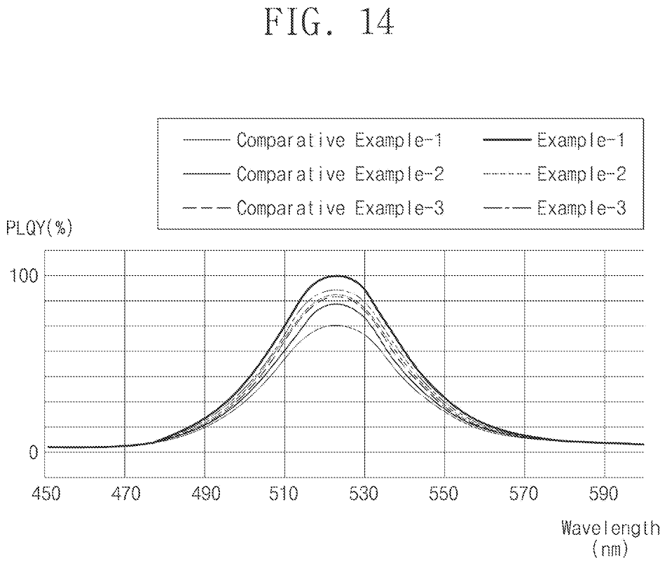

FIG. 13 is a cross-sectional view of a display device DD-1 according to another embodiment of the present disclosure. Hereinafter, in the description of the display device DD-1 of an embodiment, duplicated descriptions as those described above with reference to FIGS. 1 to 12 will not be given again, and the differences will be mainly described.

Referring to FIG. 13, the display device DD-1 according to an embodiment may include a light control layer CCL disposed on a display panel DP-1. In some embodiments, the display device DD-1 according to an embodiment may further include a color filter layer CFL. The color filter layer CFL may be disposed between the base layer BL and the light control layer CCL.

The display panel DP-1 may be a light emitting display panel. For example, the display panel DP-1 may be an organic electroluminescence display panel or a quantum dot light emitting display panel.

The display panel DP-1 may include a base substrate BS, a circuit layer DP-CL provided on the base substrate BS, and a display element layer DP-EL1.

In an embodiment, the light emitting diode layer DP-EL1 may include a light emitting diode ED-a, and the light emitting diode ED-a may include a first electrode EL1 and a second electrode EL2 facing each other, and a plurality of functional layers OL disposed between the first electrode EL1 and the second electrode EL2. The plurality of layers OL may include a hole transport region HTR (FIG. 4), an emission layer EL (FIG. 4), and an electron transport region ETR (FIG. 4). An encapsulation layer TFE may be further disposed on the light emitting diode ED-a.

In the light emitting diode ED-a, the same description as the one described with reference to FIG. 4 may be applied to the first electrode EL1, the hole transport region HTR, the electron transport region ETR, and the second electrode EL2. Yet, in the light emitting diode ED-a included in the display panel DP-1 of an embodiment, the emission layer may include a host and a dopant, which are organic electroluminescence materials or may include the quantum dot composite described above with reference to FIGS. 1 to 12. In the display panel DP-1 of an embodiment, the light emitting diode ED-a may be to emit blue light.

The light control layer CCL may include a plurality of barrier ribs BK disposed spaced apart from each other and light control units CCP-B, CCP-G, and CCP-R disposed between the barrier ribs BK. The barrier ribs BK may be formed from a material including a polymer resin and a coloring additive. The barrier ribs BK may be formed from a material including a light absorbing material, or formed from a material including a pigment and/or a dye. For example, the barrier ribs BK may include a black pigment and/or a black dye to implement a black barrier rib. When forming the black barrier rib, carbon black and/or the like may be utilized as a black pigment and/or a black dye, but the embodiment of the present disclosure is not limited thereto.

The light control layer CCL may include a first light control unit CCP-B configured to transmit a first light, a second light control unit CCP-G including a second quantum dot composite QD-C2a configured to convert the first light to a second light, and a third light control unit CCP-R including a third quantum dot composite QD-C3a configured to convert the first light to a third light. The second light may be light of a longer wavelength range than the first light, and the third light may be light of a longer wavelength range than each of the first light and the second light. For example, the first light may be blue light, the second light may be green light, and the third light may be red light. The descriptions of the quantum dot composites QD-C1, QD-C2, and QD-C3 utilized in the emission layers EL-B, EL-G, and EL-R shown in FIG. 12 above may be equally applied to quantum dot composites QD-C2a and QD-C3a included in the light control units CCP-B, CCP-G, and CCP-R.

The light control layer CCL may further include a capping layer CPL. The capping layer CPL may be disposed above the light control units CCP-B, CCP-G, and CCP-R, and the barrier ribs BK. The capping layer CPL may serve to prevent or reduce penetration of moisture and/or oxygen (hereinafter, referred to as “moisture/oxygen”). The capping layer may be disposed on the light control units CCP-B, CCP-G, and CCP-R to prevent or reduce the light control units CCP-B, CCP-G, and CCP-R from being exposed to moisture/oxygen. The capping layer CPL may include at least one inorganic layer.

The display device DD-1 of an embodiment may include a color filter layer CFL disposed on the light control layer CCL, and the descriptions in connection with FIG. 12 may be equally applied to the color filter layer CFL and the base layer BL.

The display device DD-1 according to an embodiment may include the quantum dot composites QD-C2a and QD-C3a having three different ligands (e.g., three different kinds of ligands) bonded to the quantum dot in the light control layer CCL to exhibit excellent or suitable color reproducibility.

In some embodiments, in the display device DD-1 according to an embodiment, the light emitting diode ED-a of the display panel DP-1 may include an emission layer including a quantum dot composite to which three different ligands (e.g., three different kinds of ligands) are bonded, and in this case, the display panel DP-1 may exhibit excellent or suitable luminous efficiency.

Hereinafter, with reference to specific Examples and Comparative Examples, a quantum dot composite according to an embodiment of the present disclosure and a light emitting diode including the same will be described in more detail. In addition, the Examples shown below are illustrated only for the understanding of the present disclosure, and the scope of the present disclosure is not limited thereto. Quantum yield measurement of quantum dot composites

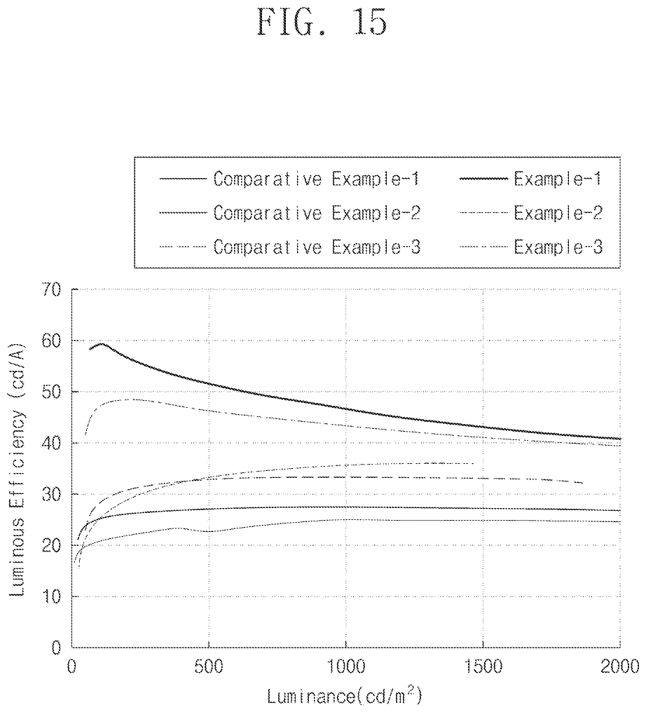

Photoluminescence quantum yield PLQY of quantum dot composites of an embodiment in which three different ligands (e.g., three different kinds of ligands) according to an embodiment of the present disclosure are bonded to a surface of a quantum dot, and the quantum dot composites of Comparative Examples in which one or two ligands are bonded to a surface of a quantum dot was measured respectively, and results are shown in Table 1 and FIG. 14.

TABLE 1

| | Ligand | | |
|---|---|---|---|
| Item | Name of ligand | Type of ligand | PLQY (%) |
| Example 1 | Chloride ion(Cl⁻) | First ligand | 99.4 |
| | Zinc dodecanthiol | Second ligand | |
| | (C₁₂H₂₅SZn) | | |
| | Octyl amine (C₈H₁₉N) | Third ligand | |
| Example 2 | Benzoate (C₇H₅O₂⁻) | First ligand | 88.8 |
| | Zinc dodecanthiol | Second ligand | |
| | (C₁₂H₂₅SZn) | | |
| | Octyl amine (C₈H₁₉N) | Third ligand | |
| Example 3 | Chloride ion (Cl⁻) | First ligand | 92.3 |
| | Zinc dodecanthiol | Second ligand | |
| | (C₁₂H₂₅SZn) | | |
| | Triethyl phosphine | Third ligand | |
| | ((C₂H₅)₃P) | | |
| Comparative | Benzoate (C₇H₅O₂⁻) | First ligand | 71.0 |
| Example 1 | | | |
| Comparative | Benzoate (C₇H₅O₂⁻) | First ligand | 78.1 |
| Example 2 | Dodecanthiolate (C₁₂H₂₅S⁻) | First ligand | |
| Comparative | Benzoate (C₇H₅O₂⁻) | First ligand | 87.3 |
| Example 3 | Octyl amine (C₈H₁₉N) | Third ligand | |
| Comparative | Chloride ion (Cl⁻) | First ligand | 83.0 |
| Example 4 | Zinc dodecanthiol | Second ligand | |
| | (C₁₂H₂₅SZn) | | |

PLQY in Table 1 indicates PLQY values at a wavelength of 523 nm. Looking at the results of Table 1 and FIG. 14, as for the quantum dot composite including all of a first ligand having an electron-donating head portion, a second ligand having an electron-withdrawing head portion, and a third ligand having a coordination-binding head portion as in the Examples, it is seen that the PLQY values are higher than those of the quantum dot composites of the Comparative Examples. As for the quantum dot composites of the Comparative Examples, one or two ligands are bonded to the surface of the quantum dot, and at least one of the first ligand to the third ligand is not included, and accordingly, it is seen that PLQY is lower than that of the quantum dot composites of the Examples.

### Measurement of Diode Efficiency and Lifespan of Light Emitting Diodes

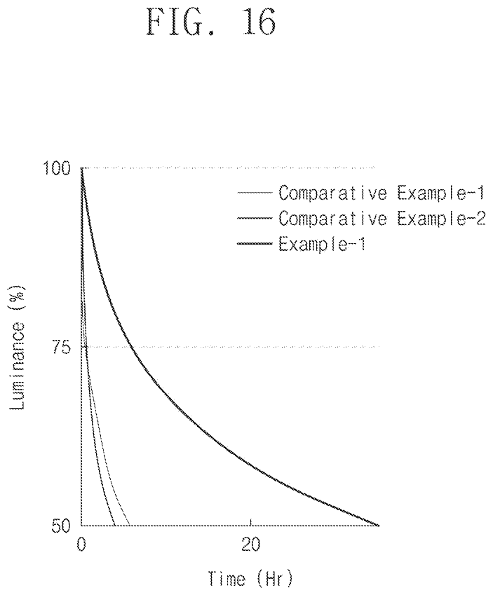

Diode luminous efficiency, maximum quantum efficiency, and full width at half maximum were measured for light emitting diodes including an emission layer formed utilizing the quantum dot composites of an embodiment (in which three different kinds of ligands according to an embodiment of the present disclosure are bonded to a surface of a quantum dot), and the quantum dot composites of the Comparative Examples (in which one or two ligands are bonded to a surface of a quantum dot), respectively, and the results are shown in Table 2 and FIG. 15.

TABLE 2

| | | | | Maximum | Full width |
|---|---|---|---|---|---|
| | | | Luminous | quantum | of half |
| | Ligand | | efficiency | efficiency | maximum |
| Item | Name of ligand | Type of ligand | (Cd/A) | (%) | (Nm) |
| Example 1 | Chloride ion (Cl⁻) | First ligand | 43.5 | 13.1 | 41 |
| | Zinc dodecanthiol | Second ligand | | | |
| | (C₁₂H₂₅SZn) | | | | |
| | Octyl amine | Third ligand | | | |
| | (C₈H₁₉N) | | | | |
| Example 2 | Benzoate | First ligand | 36.1 | 11.0 | 39 |
| | (C₇H₅O₂⁻) | | | | |
| | Zinc dodecanthiol | Second ligand | | | |
| | (C₁₂H₂₅SZn) | | | | |
| | Octyl amine | Third ligand | | | |
| | (C₈H₁₉N) | | | | |
| Example 3 | Chloride ion (Cl⁻) | First ligand | 41.4 | 12.5 | 41 |
| | Zinc dodecanthiol | Second ligand | | | |
| | (C₁₂H₂₅SZn) | | | | |
| | Triethyl phosphine | Third ligand | | | |
| | ((C₂H₅)₃P) | | | | |
| Comparative | Benzoate | First ligand | 24.9 | 7.6 | 38 |
| Example 1 | (C₇H₅O₂⁻) | | | | |
| Comparative | Benzoate | First ligand | 27.4 | 8.3 | 39 |
| Example 2 | (C₇H₅O₂⁻) | | | | |
| | Dodecanthiolate | First ligand | | | |
| | (C₁₂H₂₅S⁻) | | | | |
| Comparative | Benzoate | First ligand | 33.1 | 10.1 | 39 |
| Example 3 | (C₇H₅O₂⁻) | | | | |
| | Octyl amine | Third ligand | | | |
| | (C₈H₁₉N) | | | | |
| Comparative | Chloride ion (Cl⁻) | First ligand | 28.0 | 7.7 | 40 |
| Example 4 | Zinc dodecanthiol | Second ligand | | | |
| | (C₁₂H₂₅SZn) | | | | |

The luminous efficiency in Table 2 shows the luminous efficiency value at a luminance of 1500 cd/m². Looking at the results of Table 2 and FIG. 15, when the quantum dot composites each including all of a first ligand having an electron-donating head portion, a second ligand having an electron-withdrawing head portion, and a third ligand having a coordination-binding head portion were applied to a light emitting diode as in the Examples, it is seen that the quantum dot composites of the Examples showed about the same full width at half maximum but higher luminous efficiency and higher maximum quantum efficiency values of the diode than when the quantum dot composites of the Comparative Examples were applied to the light emitting diode. It is confirmed that, Example 2 is shown to have a slightly lower diode luminous efficiency at a low luminance of 500 cd/m² or less but to have a higher luminous efficiency at a high luminance of greater than 500 cd/m² than the Comparative Examples. As for the quantum dot composites of the Comparative Examples, one or two ligands are bonded to the surface of the quantum dot, and at least one of the first ligand to the third ligand is not included, and accordingly, when applied to the light emitting diode, it is seen that the luminous efficiency and the maximum quantum efficiency are shown to be lower than the quantum dot composites of the Examples. In addition, looking at the results of FIG. 16, when the quantum dot composite of Example 1 was applied to the light emitting diode, it is seen that a decrease in luminance over time was greatly improved compared to when the quantum dot composites of Comparative Examples 1 and 2 were applied to the light emitting diode. Accordingly, it is confirmed that when the quantum dot composites of the Examples are applied to the light emitting diode, the lifespan of the light emitting diode may be increased compared to when the quantum dot composites of Comparative Examples are applied to the light emitting diode.

As used herein, expressions such as “at least one of”, “one of”, and “selected from”, when preceding a list of elements, modify the entire list of elements and do not modify the individual elements of the list. For example, “at least one of a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof. Further, the use of “may” when describing embodiments of the present invention refers to “one or more embodiments of the present invention.”

As used herein, the terms “substantially,” “about,” and similar terms are used as terms of approximation and not as terms of degree, and are intended to account for the inherent deviations in measured or calculated values that would be recognized by those of ordinary skill in the art. Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic apparatus and/or any other relevant devices or components according to embodiments of the present invention described herein may be implemented utilizing any suitable hardware, firmware (e.g. an application-specific integrated circuit), software, or a combination of software, firmware, and hardware. For example, the various components of the apparatus may be formed on one integrated circuit (IC) chip or on separate IC chips. Further, the various components of the [device] may be implemented on a flexible printed circuit film, a tape carrier package (TCP), a printed circuit board (PCB), or formed on one substrate. Further, the various components of the apparatus may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments.

Although the present disclosure has been described with reference to a preferred embodiment of the present disclosure, it will be understood that the present disclosure should not be limited to these preferred embodiments but one or more suitable changes and modifications can be made by those skilled in the art without departing from the spirit and scope of the present disclosure. Hence, the technical scope of the present disclosure is not limited to the detailed descriptions in the specification, but it should be determined only by reference of the claims and equivalents thereof.

What is claimed is:

1. A quantum dot composite comprising:
a quantum dot having a surface comprising a plurality of binding portions; and
a ligand bonded to the surface of the quantum dot,
wherein the plurality of binding portions comprises:
a first binding portion in which cations are exposed;
a second binding portion in which anions are exposed; and
a third binding portion in which the cations and the anions are bonded to each other and exposed, and
the ligand comprises:
a first ligand bonded to the first binding portion;
a second ligand bonded to the second binding portion; and
a third ligand bonded to the third binding portion.

2. The quantum dot composite of claim 1, wherein:
the first ligand comprises an electron-donating head portion bonded to the first binding portion;
the second ligand comprises an electron-withdrawing head portion bonded to the second binding portion; and
the third ligand comprises a coordination-binding head portion bonded to the third binding portion.

3. The quantum dot composite of claim 2, wherein:
the electron-donating head portion comprises at least one group selected from halide ions, carboxylate, phosphinate, phosphonate, phosphonic acid anhydride, alkoxylate, dithiolate, and thiolate;
the electron-withdrawing head portion comprises at least one metal atom selected from Mg, Ca, Sc, Sn, Ti, V, Cr, Mn, Fe, Co, Ni, Cu, Zn, Ga, Sr, Y, Zr, Nb, Mo, Cd, In, Ba, Au, Hg, and Tl; and
the coordination-binding head portion comprises at least one group selected from phosphine, phosphine oxide, amine, imidazole, and pyridine.

4. The quantum dot composite of claim 2, wherein at least one of the first ligand, the second ligand, or the third ligand further comprises a tail portion, and
the tail portion comprises a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms.

5. The quantum dot composite of claim 4, wherein:
the first ligand comprises the electron-donating head portion, and a first tail portion connected to the electron-donating head portion;
the second ligand comprises the electron-withdrawing head portion, a connection portion connected to the electron-withdrawing head portion, and a second tail portion connected to the connection portion; and
the third ligand comprises the coordination-binding head portion and a third tail portion connected to the coordination-binding head portion.

6. The quantum dot composite of claim 1, wherein the quantum dot comprises a core and a shell around the core.

7. The quantum dot composite of claim 6, wherein the first binding portion, the second binding portion, and the third binding portion are each provided on a surface of the shell.

8. The quantum dot composite of claim 6, wherein:
the core comprises a first semiconductor nanocrystal;
the shell comprises a second semiconductor nanocrystal different from the first semiconductor nanocrystal; and
the first semiconductor nanocrystal and the second semiconductor nanocrystal are each selected from a Group II-VI compound, a Group III-V compound, a Group IV-VI compound, a Group IV element, a Group IV compound, and a combination thereof.

9. The quantum dot composite of claim 8, wherein the second semiconductor nanocrystal is in a state of having the cations and the anions bonded to each other.

10. The quantum dot composite of claim 1, wherein the first ligand is represented by Formula 1-1 or Formula 1-2, the second ligand is represented by Formula 2, and the third ligand is represented by Formula 3:
A₁-R₁, Formula 1-1
wherein in Formula 1-1,
A₁ is a group selected from carboxylate, phosphinate, phosphonate, phosphonic acid anhydride, alkoxylate, dithiolate, and thiolate, and
R₁ is a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms;
A₂, Formula 1-2
wherein in Formula 1-2,
A₂ is a halide ion;
M-A₃-R₂, Formula 2
wherein in Formula 2,
M is a metal atom selected from Mg, Ca, Sc, Sn, Ti, V, Cr, Mn, Fe, Co, Ni, Cu, Zn, Ga, Sr, Y, Zr, Nb, Mo, Cd, In, Ba, Au, Hg, and Tl,
A₃ is at least one group selected from carboxylate, phosphinate, phosphonate, phosphonic acid anhydride, alkoxylate, dithiolate, and thiolate, and
R₂ is a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms; and
A₄-R₃, Formula 3
wherein in Formula 3,
A₄ is at least one group selected from phosphine, phosphine oxide, amine, imidazole, and pyridine, and
R₃ is a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms.

11. A quantum dot composite comprising:
a quantum dot having a surface; and
a ligand bonded to the surface of the quantum dot,
wherein the ligand comprises:
a first ligand comprising an electron-donating head portion;
a second ligand comprising an electron-withdrawing head portion; and
a third ligand comprising a coordination-binding head portion.

12. The quantum dot composite of claim 11, wherein:
the quantum dot comprises a core and a shell around the core; and
the electron-donating head portion, the electron-withdrawing head portion, and the coordination-binding head portion are each bonded to a surface of the shell.

13. A light emitting diode comprising:
a first electrode;
a hole transport region on the first electrode;
an emission layer on the hole transport region and comprising a quantum dot composite comprising a ligand;
an electron transport region on the emission layer; and
a second electrode on the electron transport region,
wherein the quantum dot composite comprises:
a quantum dot having a surface; and
the ligand bonded to the surface of the quantum dot,
wherein the surface of the quantum dot comprises a plurality of binding portions, the plurality of binding portions comprising:
a first binding portion in which cations are exposed;
a second binding portion in which anions are exposed; and
a third binding portion in which cations and anions are bonded to each other and exposed, and
the ligand comprises:
a first ligand bonded to the first binding portion;
a second ligand bonded to the second binding portion; and
a third ligand bonded to the third binding portion.

14. The light emitting diode of claim 13, wherein the electron transport region comprises:
an electron transport layer on the emission layer; and
an electron injection layer between the electron transport layer and the second electrode, and
wherein the electron transport layer comprises a metal oxide.

15. The light emitting diode of claim 13, wherein the emission layer has a central emission wavelength of about 500 nm to about 540 nm.

16. The light emitting diode of claim 13, wherein:
the first ligand comprises an electron-donating head portion bonded to the first binding portion;
the second ligand comprises an electron-withdrawing head portion bonded to the second binding portion; and
the third ligand comprises a coordination-binding head portion bonded to the third binding portion.

17. The light emitting diode of claim 16, wherein:
the electron-donating head portion comprises at least one group selected from halide ions, carboxylate, phosphinate, phosphonate, phosphonic acid anhydride, alkoxylate, dithiolate, and thiolate;
the electron-withdrawing head portion is at least one metal atom selected from Mg, Ca, Sc, Sn, Ti, V, Cr, Mn, Fe, Co, Ni, Cu, Zn, Ga, Sr, Y, Zr, Nb, Mo, Cd, In, Ba, Au, Hg, and Tl; and
the coordination-binding head portion is at least one group selected from phosphine, phosphine oxide, amine, imidazole, and pyridine.

18. The light emitting diode of claim 13, wherein the quantum dot comprises a core and a shell around the core.

19. The light emitting diode of claim 18, wherein:
the core comprises a first semiconductor nanocrystal;
the shell comprises a second semiconductor nanocrystal different from the first semiconductor nanocrystal;
the first semiconductor nanocrystal and the second semiconductor nanocrystal are each selected from a Group II-VI compound, a Group III-V compound, a Group IV-VI compound, a Group IV element, a Group IV compound, and a combination thereof; and
the first binding portion, the second binding portion, and the third binding portion are each provided on a surface of the shell.

20. The light emitting diode of claim 13, wherein the first ligand is represented by Formula 1-1 or Formula 1-2, the second ligand is represented by Formula 2, and the third ligand is represented by Formula 3:
A₁-R₁, Formula 1-1
wherein in Formula 1-1,
A₁ is at least one group selected from carboxylate, phosphinate, phosphonate, phosphonic acid anhydride, alkoxylate, dithiolate, and thiolate, and
R₁ is a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms;
A₂, Formula 1-2
wherein in Formula 1-2,
A₂ is a halide ion;
M-A₃-R₂, Formula 2
wherein in Formula 2,
M is at least one metal atom selected from Mg, Ca, Sc, Sn, Ti, V, Cr, Mn, Fe, Co, Ni, Cu, Zn, Ga, Sr, Y, Zr, Nb, Mo, Cd, In, Ba, Au, Hg, and Tl,
A₃ is at least one group selected from carboxylate, phosphinate, phosphonate, phosphonic acid anhydride, alkoxylate, dithiolate, and thiolate, and
R₂ is a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms; and
A₄-R₃, Formula 3
wherein in Formula 3,
A₄ is at least one group selected from phosphine, phosphine oxide, amine, imidazole, and pyridine, and
R₃ is a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms.
